(19) United States
(12) Patent Application Publication
(10) Pub. No.: US 2025/0004036 A1
(43) Pub. Date: Jan. 2, 2025

(54) DISPLAY DEVICE AND INSPECTION METHOD USING DISPLAY DEVICE

(71) Applicant: Sharp Display Technology Corporation, Kameyama City, Mie (JP)

(72) Inventors: Masahiro MITANI, Kameyama City, Mie (JP); Naoki UEDA, Kameyama City, Mie (JP); Asahi YAMATO, Kameyama City, Mie (JP)

(21) Appl. No.: 18/697,955

(22) PCT Filed: Dec. 10, 2021
(86) PCT No.: PCT/JP2021/045681

§ 371 Date: Apr. 2, 2024

(51) Int. Cl. G01R 31/26; G09G 3/00; H10K 59/131; H10K 59/80

(52) U.S. Cl. CPC G01R 31/2635; G09G 3/006; H10K 59/131; H10K 59/873

(57) ABSTRACT

A display device includes a display region;
a frame region around a periphery of the display region; a terminal portion including a first terminal and a second terminal, and a plurality of input terminals provided between the first terminal and the second terminal and connected respectively to a plurality of first signal lines extending from the display region and in a signal line formation region of the frame region; and a plurality of crack detection wiring lines provided in the frame region, the plurality of crack detection wiring lines each including a first end and a second end disposed on either side of the signal line formation region, wherein each first end of the plurality of crack detection wiring lines is electrically connected to the first terminal, and each second end of the plurality of crack detection wiring lines is electrically connected to the second terminal.

### TECHNICAL FIELD

The disclosure relates to a display device and an inspection method using a display device.

### BACKGROUND ART

In the field of display devices, in order to realize a display device having higher reliability, a technique for detecting the presence or absence of cracking in the inspection stage before product shipment is developed.

In recent years, various display devices provided with light-emitting elements are developed. In particular, in the field of display devices provided with a quantum dot light-emitting diode (QLED) or an organic light-emitting diode (OLED), if a crack occurs, it leads to a degradation in the reliability of the QLED or OLED due to moisture and the like entering through the crack. Thus, importance is placed on techniques for detecting the presence or absence of cracking in the inspection stage before product shipment.

For example, PTLs 1 to 4 describe detecting the presence or absence of cracking in a display device using a crack detection wiring line formed of a single wire.

### CITATION LIST

### Patent Literature

PTL 1: JP 2014-122974 A
PTL 2: JP 2012-220792 A
PTL 3: JP 2011-149979 A
PTL 4: JP 2006-258746 A

### SUMMARY

### Technical Problem

However, as described in PTLs 1 to 4, in the case of detecting the presence or absence of cracking in a display device using a crack detection wiring line formed of a single wire, it is possible to detect the presence or absence of a crack, but it is not possible to detect how fatal the formed crack is to the reliability of the display device (for example, how large or deep the formed crack is), whether the formed crack has propagation propensity, and the like.

Therefore, as described above, when the presence or absence of cracking in a display device is detected using a crack detection wiring line formed of a single wire, even if the formed crack is not fatal to the reliability of the display device or the formed crack is not a crack with propagation propensity, if cracking is detected, it cannot be classified as a non-defective product in the inspection stage before product shipment. This problem leads to a decrease in the yield (non-defect rate) of the display device and an increase in the manufacturing costs of the display device.

An aspect of the disclosure has been conceived in consideration of the above-mentioned problem, and an object thereof is to provide a display device that can achieve an improvement in yield (non-defect rate) and a reduction in manufacturing costs and an inspection method using a display device.

### Solution to Problem

To solve the problems described above, a display device according to the disclosure includes:
a display region;
a frame region around a periphery of the display region;
a terminal portion including
a first terminal and a second terminal forming a pair of inspection terminals, and
a plurality of input terminals provided between the first terminal and the second terminal and connected respectively to a plurality of first signal lines extending from the display region and in a signal line formation region of the frame region; and
a plurality of crack detection wiring lines provided in the frame region, the plurality of crack detection wiring lines each including a first end and a second end disposed on either side of the signal line formation region,
wherein each first end of the plurality of crack detection wiring lines is electrically connected to the first terminal, the first terminal being closer to the first end than the second terminal, and
each second end of the plurality of crack detection wiring lines is electrically connected to the second terminal, the second terminal being closer to the second end than the first terminal.

To solve the problems described above, a display device according to the disclosure includes:
a display region;
a frame region around a periphery of the display region;
a terminal portion including
a first terminal and a second terminal forming a pair of inspection terminals, and
a plurality of input terminals provided between the first terminal and the second terminal and connected respectively to a plurality of first signal lines extending from the display region and in a signal line formation region of the frame region; and
a plurality of crack detection wiring lines provided in the frame region, the plurality of crack detection wiring lines each including a first end and a second end disposed on either side of the signal line formation region,
wherein an electrical connection between the first end of one crack detection wiring line selected from the plurality of crack detection wiring lines and the first terminal and an electrical connection between the second end and the second terminal are performed in a first period, and
an electrical connection between the first end of a different crack detection wiring line selected from the plurality of crack detection wiring lines and the first terminal and an electrical connection between the second end and the second terminal are performed in a second period different from the first period.

To solve the problems described above, an inspection method using a display device according to the disclosure includes:
performing a first crack detection using a display device including a display region, a frame region around a periphery of the display region, a terminal portion including a first terminal and a second terminal forming a pair of inspection terminals, and a plurality of input terminals provided between the first terminal and the second terminal and connected respectively to a plurality of first signal lines extending from the display region and in a signal line formation region of the frame region, and a plurality of crack detection wiring lines provided in the frame region, the plurality of crack detection wiring lines each including a first end and a second end disposed on either side of the signal line formation region,
wherein, in the first crack detection,
a degree of crack propagation of the display device is determined on a basis of resistance values of the plurality of crack detection wiring lines measured via the first terminal and the second terminal.

### Advantageous Effects of Disclosure

An aspect of the disclosure can provide a display device that can achieve an improvement in yield (non-defect rate) and a reduction in manufacturing costs and an inspection method using a display device.

### BRIEF DESCRIPTION OF DRAWINGS

FIG. 1 is a plan view illustrating a schematic configuration of a display device according to a first embodiment.

FIG. 2 is a schematic cross-sectional view illustrating a configuration of the display device according to the first embodiment taken along line A-A′ illustrated in FIG. 1.

FIG. 3 is a diagram illustrating an example of an inspection method using the display device according to the first embodiment.

FIGS. 4(a), (b), and (c) are diagrams for describing the preferable resistance ratio due to the variation in resistance value measured according to an example of an inspection method using the display device according to the first embodiment illustrated in FIG. 3.

FIG. 5 is a diagram illustrating another example of an inspection method using the display device according to the first embodiment.

FIGS. 6(a), (b), and (c) are diagrams for describing the preferable resistance ratio due to the variation in resistance value measured according to another example of an inspection method using the display device according to the first embodiment illustrated in FIG. 5.

FIG. 7 is a schematic plan view illustrating a configuration of a display device according to a first modified example of the first embodiment.

FIG. 8 is a schematic plan view illustrating a configuration of a display device according to a second modified example of the first embodiment.

FIG. 9 is a plan view illustrating a schematic configuration of a display device according to a second embodiment.

FIG. 10 is a schematic plan view illustrating a configuration of a display device according to a third embodiment.

FIG. 11 is a schematic plan view illustrating a configuration of a display device according to a fourth embodiment.

FIG. 12 is a schematic plan view illustrating a configuration of a display device according to a fifth embodiment.

FIG. 13 is a diagram illustrating an example of an inspection method using the display device according to the fifth embodiment.

FIG. 14 is a schematic plan view illustrating a configuration of a display device according to a sixth embodiment.

FIG. 15 (a) is a diagram showing the resistance values of crack detection wiring lines forming a plurality of crack detection wiring lines provided in a first example of the display device of the sixth embodiment. FIGS. 15(b) and (c) are diagrams showing the change in resistance values measured via the first terminal and the second terminal according to the number of disconnections in the case of the crack detection wiring lines forming the first to fifth lines provided in the first example of the display device of the sixth embodiment.

FIG. 16 (a) is a diagram showing the resistance values of crack detection wiring lines forming a plurality of crack detection wiring lines provided in a second example of the display device of the sixth embodiment. FIGS. 16(b) and (c) are diagrams showing the change in resistance values measured via the first terminal and the second terminal according to the number of disconnections in the case of the crack detection wiring lines forming the first to fifth lines provided in the second example of the display device of the sixth embodiment.

FIG. 17 (a) is a diagram showing the resistance values of crack detection wiring lines forming a plurality of crack detection wiring lines provided in a third example of the display device of the sixth embodiment. FIGS. 17(b) and (c) are diagrams showing the change in resistance values measured via the first terminal and the second terminal according to the number of disconnections in the case of the crack detection wiring lines forming the first to fifth lines provided in the third example of the display device of the sixth embodiment.

FIG. 18 is a schematic plan view illustrating a configuration of a display device according to a seventh embodiment.

### DESCRIPTION OF EMBODIMENTS

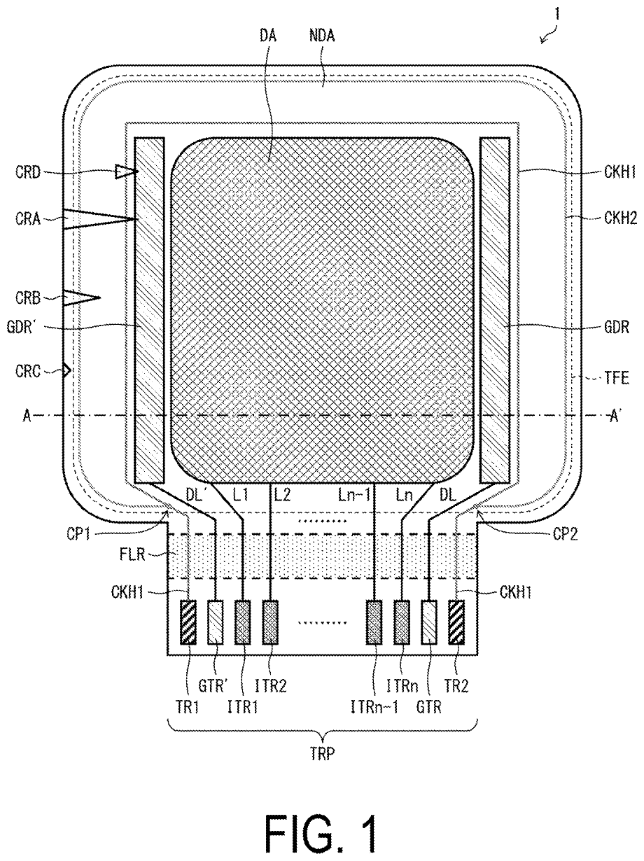

Embodiments of the disclosure will be described below with reference to FIG. 1 to FIG. 18. Hereinafter, for convenience of description, configurations having the same functions as those described in a specific embodiment are denoted by the same reference signs, and descriptions thereof will be omitted.

### First Embodiment

FIG. 1 is a schematic plan view illustrating a configuration of a display device 1 according to a first embodiment.

As illustrated in FIG. 1, a display device 1 includes a display region DA, a frame region NDA around the periphery of the display region DA, a terminal portion TRP including a first terminal TR1 and a second terminal TR2 forming a pair of inspection terminals and a plurality of input terminals ITR1 to ITRn provided between the first terminal TR1 and the second terminal TR2 and connected to a plurality of first signal lines L1 to Ln extending from the display region DA to a signal line formation region of the frame region NDA, and a plurality of crack detection wiring lines CKH1 and CKH2 provided in the frame region NDA, the plurality of crack detection wiring lines CKH1 and CKH2 each including a first end (end on the left side at a contact point CP1 in the diagram) and a second end (end on the right side at a contact point CP2 in the diagram) disposed on either side of the signal line formation region. Note that the terminal portion TRP is formed as a portion of the frame region NDA.

The first ends (ends on the left side at the contact point CP1 in the diagram) of the plurality of crack detection wiring lines CKH1 and CKH2 are electrically connected to the closer first terminal TR1, from among the first terminal TR1 and the second terminal TR2, and the second ends (ends on the right side at the contact point CP2 in the diagram) of the plurality of crack detection wiring lines CKH1 and CKH2 are electrically connected to the closer second terminal TR2, from among the first terminal TR1 and the second terminal TR2.

Though not illustrated, a plurality of pixels are provided in the display region DA of the display device 1, and each pixel includes a red subpixel, a green subpixel, and a blue subpixel. In the example of the present embodiment described herein, one pixel includes a red subpixel, a green subpixel, and a blue subpixel, but no such limitation is intended. For example, one pixel may further include a subpixel of another color in addition to the red subpixel, the green subpixel, and the blue subpixel.

In the example of the present embodiment described herein, the plurality of crack detection wiring lines include two wiring lines, namely the crack detection wiring line CKH1 and the crack detection wiring line CKH2. However, the number is not particularly limited as long as it is two or greater. For example, as described in the fifth embodiment described below, the plurality of crack detection wiring lines may be formed of three wiring lines, or as described in the sixth embodiment described below, the plurality of crack detection wiring lines may be formed of five wiring lines.

As illustrated in FIG. 1, in the example of the display device 1 according to the present embodiment described herein, the crack detection wiring line CKH2 is provided around the periphery from the first end (end on the left side at the contact point CP1 in the diagram) of the crack detection wiring line CKH1 to the second end (end on the right side at the contact point CP2 in the diagram), but no such limitation is intended. In a case where the crack detection wiring line CKH1 and the crack detection wiring line CKH2 are formed in different layers, the crack detection wiring line CKH1 and the crack detection wiring line CKH2 may be formed overlapping one another in a plan view (the display device 1 as seen from the display surface side).

As with the display device 1 according to the present embodiment, in a case where the crack detection wiring line CKH2 is provided around the periphery from the first end (end on the left side at the contact point CP1 in the diagram) of the crack detection wiring line CKH1 to the second end (end on the right side at the contact point CP2 in the diagram), for example, for a plurality of cracks CRA, CRB, and CRC illustrated in FIG. 1 formed from the outer side of the display device 1 (outer shape of the display device 1), how long the cracks are from the outer side of the display device 1, that is, how much distance from the outer shape of the display device 1 have the formed cracks propagated toward the inner side of the display device 1, can be detected, and how fatal the formed cracks are to the reliability of the display device can be detected. Whether or not the crack is a crack with propagation propensity can also be determined.

On the other hand, in a case where the crack detection wiring line CKH1 and the crack detection wiring line CKH2 are formed overlapping one another in a plan view, in a case where a formed crack is a level crack that can be visually observed to reach the crack detection wiring lines provided overlapping in a plan view, for example the crack CRA illustrated in FIG. 1, how deep the crack CRA has run in the film thickness direction can be detected, and how fatal the formed crack is to the reliability of the display device can be detected. Whether or not the crack is a crack with propagation propensity can also be detected.

As illustrated in FIG. 1, in the display device 1 according to the present embodiment, the first end (end on the left side at the contact point CP1 in the diagram) of the crack detection wiring line CKH1, which is one of the crack detection wiring line CKH1 and the crack detection wiring line CKH2, extends to the first terminal TR1 and is connected to the first terminal TR1, and the first end (end on the left side at the contact point CP1 in the diagram) of the crack detection wiring line CKH2, which is the other one of the crack detection wiring line CKH1 connected to the first terminal TR1, is electrically connected to the first terminal TR1 via the crack detection wiring line CKH1. That is, the first end (end on the left side at the contact point CP1 in the diagram) of the crack detection wiring line CKH2 is electrically connected to the crack detection wiring line CKH1 at the contact point CP1. Thus, the first end (end on the left side at the contact point CP1 in the diagram) of the crack detection wiring line CKH2 is electrically connected to the first terminal TR1 via the crack detection wiring line CKH1. Also, as illustrated in FIG. 1, the second end (end on the right side at the contact point CP2 in the diagram) of the crack detection wiring line CKH1, which is one of the crack detection wiring line CKH1 and the crack detection wiring line CKH2, extends to the second terminal TR2 and is connected to the second terminal TR2, and the second end (end on the right side at the contact point CP2 in the diagram) of the crack detection wiring line CKH2, which is the other one of the crack detection wiring line CKH1 connected to the second terminal TR2, is electrically connected to the second terminal TR2 via the crack detection wiring line CKH1. That is, the second end (end on the right side at the contact point CP2 in the diagram) of the crack detection wiring line CKH2 is electrically connected to the crack detection wiring line CKH1 at the contact point CP2. Thus, the second end (end on the right side at the contact point CP2 in the diagram) of the crack detection wiring line CKH2 is electrically connected to the second terminal TR2 via the crack detection wiring line CKH1.

As described above, in an example of the present embodiment described herein, the first end (end on the left side at the contact point CP1 in the diagram) of the crack detection wiring line CKH1 extends to the first terminal TR1 and is connected to the first terminal TR1, and the second end (end on the right side at the contact point CP2 in the diagram) of the crack detection wiring line CKH1 extends to the second terminal TR2 and is connected to the second terminal TR2. However, no such limitation is intended.

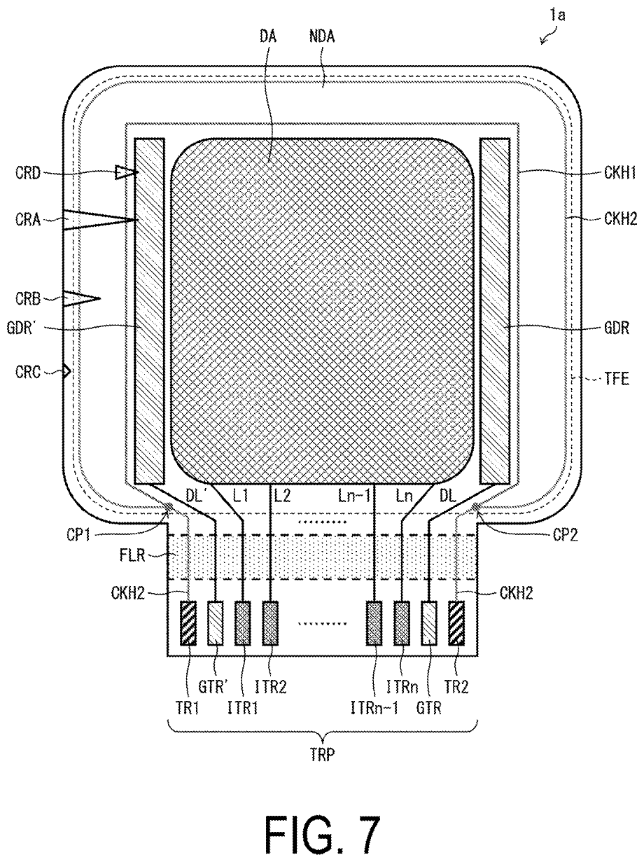

FIG. 7 is a schematic plan view illustrating a configuration of a display device 1a according to a first modified example of the first embodiment.

As in the display device 1a illustrated in FIG. 7, the first end (end on the left side at the contact point CP1 in the diagram) of the crack detection wiring line CKH2 may extend to the first terminal TR1 and be connected to the first terminal TR1, and the second end (end on the right side at the contact point CP2 in the diagram) of the crack detection wiring line CKH2 may extend to the second terminal TR2 and be connected to the second terminal TR2. In other words, the first end (end on the left side at the contact point CP1 in the diagram) of the crack detection wiring line CKH1 may be electrically connected to the crack detection wiring line CKH2 at the contact point CP1. Thus, the first end (end on the left side at the contact point CP1 in the diagram) of the crack detection wiring line CKH1 may be electrically connected to the first terminal TR1 via the crack detection wiring line CKH2. Also, the second end (end on the right side at the contact point CP2 in the diagram) of the crack detection wiring line CKH1 may be electrically connected to the crack detection wiring line CKH2 at the contact point CP2. Thus, the second end (end on the right side at the contact point CP2 in the diagram) of the crack detection wiring line CKH1 may be electrically connected to the second terminal TR2 via the crack detection wiring line CKH2.

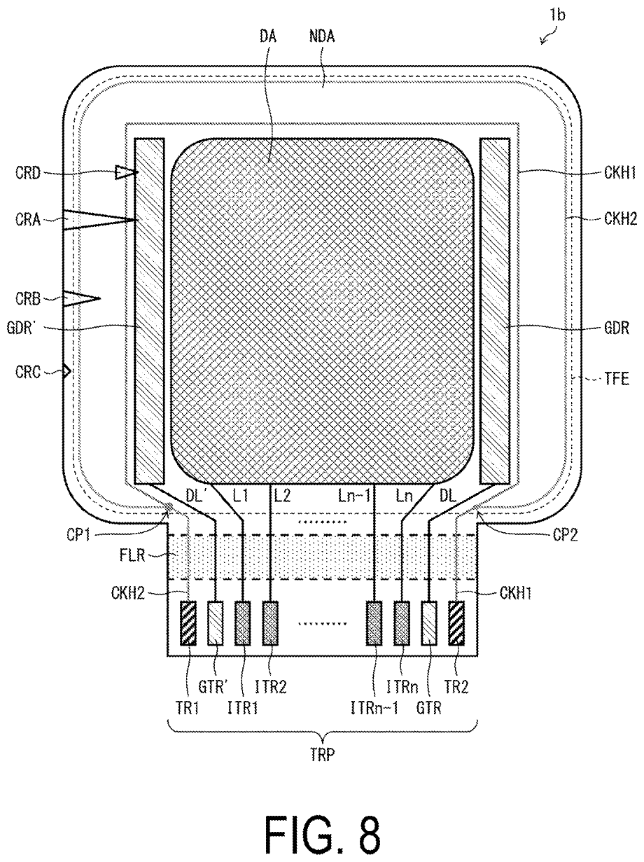

FIG. 8 is a schematic plan view illustrating a configuration of a display device 1b according to a second modified example of the first embodiment.

As in the display device 1b illustrated in FIG. 8, the first end (end on the left side at the contact point CP1 in the diagram) of the crack detection wiring line CKH2 may extend to the first terminal TR1 and be connected to the first terminal TR1, and the second end (end on the right side at the contact point CP2 in the diagram) of the crack detection wiring line CKH1 may extend to the second terminal TR2 and be connected to the second terminal TR2. In other words, the first end (end on the left side at the contact point CP1 in the diagram) of the crack detection wiring line CKH1 may be electrically connected to the crack detection wiring line CKH2 at the contact point CP1. Thus, the first end (end on the left side at the contact point CP1 in the diagram) of the crack detection wiring line CKH1 may be electrically connected to the first terminal TR1 via the crack detection wiring line CKH2. Also, the second end (end on the right side at the contact point CP2 in the diagram) of the crack detection wiring line CKH2 may be electrically connected to the crack detection wiring line CKH1 at the contact point CP2. Thus, the second end (end on the right side at the contact point CP2 in the diagram) of the crack detection wiring line CKH2 may be electrically connected to the second terminal TR2 via the crack detection wiring line CKH1.

Though not illustrated, the first end (end on the left side at the contact point CP1 in the diagram) of the crack detection wiring line CKH1 may extend to the first terminal TR1 and be connected to the first terminal TR1, and the second end (end on the right side at the contact point CP2 in the diagram) of the crack detection wiring line CKH2 may extend to the second terminal TR2 and be connected to the second terminal TR2. In other words, the first end (end on the left side at the contact point CP1 in the diagram) of the crack detection wiring line CKH2 may be electrically connected to the crack detection wiring line CKH1 at the contact point CP1. Thus, the first end (end on the left side at the contact point CP1 in the diagram) of the crack detection wiring line CKH2 may be electrically connected to the first terminal TR1 via the crack detection wiring line CKH1. Also, the second end (end on the right side at the contact point CP2 in the diagram) of the crack detection wiring line CKH1 may be electrically connected to the crack detection wiring line CKH2 at the contact point CP2. Thus, the second end (end on the right side at the contact point CP2 in the diagram) of the crack detection wiring line CKH1 may be electrically connected to the second terminal TR2 via the crack detection wiring line CKH2.

As described above, in an example of the present embodiment described herein, the first end (end on the left side at the contact point CP1 in the diagram) of one of the crack detection wiring line CKH1 and the crack detection wiring line CKH2 extends to the first terminal TR1 and is connected to the first terminal TR1, and the second end (end on the right side at the contact point CP2 in the diagram) of one of the crack detection wiring line CKH1 and the crack detection wiring line CKH2 extends to the second terminal TR2 and is connected to the second terminal TR2. However, no such limitation is intended.

For example, the first end (end on the left side at the contact point CP1 in the diagram) of the crack detection wiring line CKH1 and the first end (end on the left side at the contact point CP1 in the diagram) of the crack detection wiring line CKH2 may be bundled and electrically connected at the contact point CP1, and the electrical connection of the contact point CP1 and the first terminal TR1 may be formed using different wiring lines to the crack detection wiring line CKH1 and the crack detection wiring line CKH2. Also, the second end (end on the right side at the contact point CP2 in the diagram) of the crack detection wiring line CKH1 and the second end (end on the right side at the contact point CP2 in the diagram) of the crack detection wiring line CKH2 may be bundled and electrically connected at the contact point CP2, and the electrical connection of the contact point CP2 and the first terminal TR2 may be formed using different wiring lines to the crack detection wiring line CKH1 and the crack detection wiring line CKH2.

In the present embodiment, as illustrated in FIGS. 1, 7, and 8, in the display devices 1, la, and 1b, drive circuits (drive drivers) GDR and GDR′ are directly formed on the flexible substrate of the frame region NDA in the peripheral portion of the display region DA using a gate-on-panel (GOP) design to realize the display devices 1, 1a, and 1b with improved flexibility. However, no such limitation is intended. As illustrated in FIGS. 1, 7, and 8, in the display devices 1, 1a, and 1b, a bend wiring line region FLR is provided between the display region DA and the terminal portion TRP where the terminal portion TRP can bend relative to the display region DA. However, the bend wiring line region FLR may not be provided. The display devices 1, 1a, and 1b include the drive circuits GDR and GDR′ provided between the display region DA and the crack detection wiring line CKH1 disposed closest to the display region DA from among the plurality of crack detection wiring lines CKH1 and CKH2, drive signal input terminals GTR and GTR′ provided between the first terminal TR1 and the second terminal TR2 of the terminal portion TRP, a second signal line DL configured to electrically connect the drive circuit GDR and the drive signal input terminal GTR disposed on the right side of the display region DA and provided in the signal line formation region of the frame region NDA, and a second signal line DL′ configured to electrically connect the drive circuit GDR′ and the drive signal input terminal GTR′ disposed on the left side of the display region DA and provided in the signal line formation region of the frame region NDA. In the example of the present embodiment described herein, the two drive circuits GDR and GDR′ are provided on both the left and right sides of the display region DA. However, no such limitation is intended, and only a single drive circuit may be provided on the right side or the left side of the display region DA.

In the present embodiment, as illustrated in FIGS. 1, 7, and 8, the display devices 1, 1a, and 1b include a sealing layer TFE covering the display region DA and a portion of the frame region NDA continuing on from the display region DA. In FIGS. 1, 7, and 8, the sealing layer TFE indicated by a broken line illustrates the end portion of the sealing layer TFE. The portion of the crack detection wiring line CKH1 and the crack detection wiring line CKH2 surrounding the display region DA is covered by the sealing layer TFE. In this manner, corrosion of the wiring line can be prevented by the portion of the crack detection wiring line CKH1 and the crack detection wiring line CKH2 surrounding the display region DA being covered by the sealing layer TFE. However, no such limitation is intended, and as with a display device 1f according to the fifth embodiment described below, at least a portion of a portion surrounding the display region DA of some crack detection wiring lines including the crack detection wiring line disposed farthest from the display region DA from among the plurality of crack detection wiring lines may be provided on the outer side of the end portion of the sealing layer TFE.

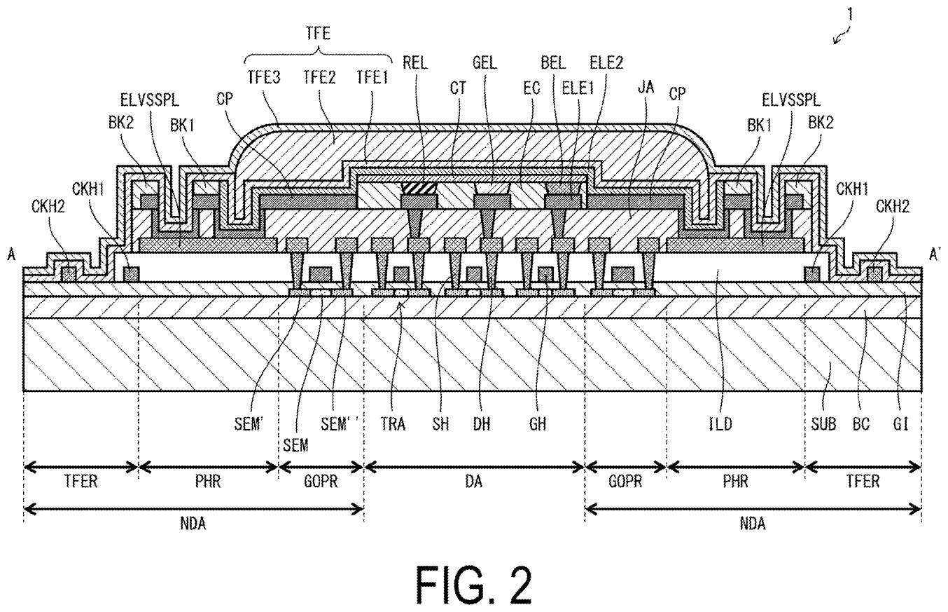

FIG. 2 is a schematic cross-sectional view illustrating a configuration of the display device 1 taken along line A-A′ illustrated in FIG. 1.

As illustrated in FIG. 2, in the display region DA of the display device 1, on a substrate SUB, a barrier layer BC; a thin film transistor layer including a transistor TRA; a red light-emitting element including a function layer REL including a red light-emitting layer, a green light-emitting element including a function layer GEL including a green light-emitting layer, and a blue light-emitting element including a function layer BEL including a blue light-emitting layer; and the sealing layer TFE are provided in this order from the substrate SUB side.

The substrate SUB may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the substrate SUB. However, no such limitation is intended. In a case where the display device 1 is a non-flexible display device, the glass substrate may be used as the substrate SUB.

The barrier layer BC is a layer that inhibits substances such as water and oxygen from entering the transistor TRA, the red light-emitting element including the function layer REL including the red light-emitting layer, the green light-emitting element including the function layer GEL including the green light-emitting layer, and the blue light-emitting element including the function layer BEL including the blue light-emitting layer and can be formed of, for example, a silicon oxide film, a silicon nitride film, or a silicon oxynitride film, or a layered film thereof formed by chemical vapor deposition (CVD).

The transistor TRA portion of the thin film transistor layer including the transistor TRA includes a semiconductor film SEM and doped semiconductor films SEM′ and SEM″, an inorganic insulating film (gate insulating film) GI, a gate electrode and a scanning line GH, an inorganic insulating film (interlayer insulating film) ILD, a source electrode and a signal line SH, a drain electrode DH, and a flattening film JA. The portion of the thin film transistor layer including the transistor TRA other than the transistor TRA portion includes the inorganic insulating film (gate insulating film) GI, the inorganic insulating film (interlayer insulating film) ILD, and the flattening film JA.

The semiconductor films SEM, SEM′ and SEM″ may be formed of low-temperature polysilicon (LTPS) or an oxide semiconductor (for example, an In—Ga—Zn—O based semiconductor), for example. In the example of the present embodiment described herein, the transistor TRA has a top gate structure. However, no such limitation is intended, and the transistor TRA may have a bottom gate structure.

The gate electrode and the scanning line GH may be formed of a single-layer film or a layered film of a metal including, for example, at least one of aluminum, tungsten, molybdenum, tantalum, chromium, titanium, silver, or copper.

The source electrode and the signal line SH and the drain electrode DH may be formed of a single-layer film or a layered film of a metal including, for example, at least one of aluminum, tungsten, molybdenum, tantalum, chromium, titanium, silver, or copper.

The inorganic insulating film (gate insulating film) GI and the inorganic insulating film (interlayer insulating film) ILD may be formed of a silicon oxide film, a silicon nitride film, or a silicon oxynitride film, or a layered film thereof, formed by CVD.

The flattening film JA may be formed of coatable organic materials such as polyimide and acrylic.

The red subpixel provided in the display region DA of the display device 1 includes a red light-emitting element including the function layer REL including the red light-emitting layer, the green subpixel provided in the display region DA of the display device 1 includes the green light-emitting element including the function layer GEL including the green light-emitting layer, and the blue subpixel provided in the display region DA of the display device 1 includes the blue light-emitting element including the function layer BEL including the blue light-emitting layer. The red light-emitting element including the function layer REL including the red light-emitting layer includes a first electrode ELE1, the function layer REL including the red light-emitting layer, a charge transfer layer CT, and a second electrode ELE2; the green light-emitting element including the function layer GEL including the green light-emitting layer includes the first electrode ELE1, the function layer GEL including the green light-emitting layer, the charge transfer layer CT, and the second electrode ELE2; and the blue light-emitting element including the function layer BEL including the blue light-emitting layer includes the first electrode ELE1, the function layer BEL including the blue light-emitting layer, the charge transfer layer CT, and the second electrode ELE2. Note that an edge cover layer EC with insulating properties covering the edge of the first electrode ELE1 is formed, for example, by applying an organic material, such as polyimide or acrylic, and then patterning the organic material by photolithography.

In the example of the present embodiment described herein, the first electrode ELE1 is an anode; the second electrode ELE2 is a cathode; the charge transfer layer CT formed as a common layer is an electron injection layer; the function layer REL including the red light-emitting layer includes a hole injection layer, a hole transport layer, the red light-emitting layer, and an electron transport layer layered in this order from the first electrode ELE1 (anode) side; the function layer GEL including the green light-emitting layer includes a hole injection layer, a hole transport layer, the green light-emitting layer, and an electron transport layer layered in this order from the first electrode ELE1 (anode) side; and the function layer BEL including the blue light-emitting layer includes a hole injection layer, a hole transport layer, the blue light-emitting layer, and an electron transport layer layered in this order from the first electrode ELE1 (anode) side. However, no such limitation is intended. For example, for the red light-emitting element including the function layer REL including the red light-emitting layer, the green light-emitting element including the function layer GEL including the green light-emitting layer, and the blue light-emitting element including the function layer BEL including the blue light-emitting layer, at least one of the electron injection layer, the electron transport layer, the hole injection layer, or the hole transport layer may be omitted.

Also, the first electrode ELE1 may be a cathode, and the second electrode ELE2 may be an anode. In this case, the charge transfer layer CT formed as a common layer is a hole injection layer; the function layer REL including the red light-emitting layer includes an electron injection layer, an electron transport layer, the red light-emitting layer, and a hole transport layer layered in this order from the first electrode ELE1 (cathode) side; the function layer GEL including the green light-emitting layer includes an electron injection layer, an electron transport layer, the green light-emitting layer, and a hole transport layer layered in this order from the first electrode ELE1 (cathode) side; and the function layer BEL including the blue light-emitting layer includes an electron injection layer, an electron transport layer, the blue light-emitting layer, and a hole transport layer layered in this order from the first electrode ELE1 (cathode) side.

The red light-emitting element including the function layer REL including the red light-emitting layer, the green light-emitting element including the function layer GEL including the green light-emitting layer, and the blue light-emitting element including the function layer BEL including the blue light-emitting layer may be top-emitting types or may be bottom-emitting types.

As illustrated in FIG. 2, in the display device 1, the second electrode ELE2 is disposed above the first electrode ELE1. Thus, to form a top-emitting type, the first electrode ELE1 is formed of an electrode material that reflects visible light and the second electrode ELE2 is formed of an electrode material that transmits visible light. To form a bottom-emitting type, the first electrode ELE1 is formed of an electrode material that transmits visible light and the second electrode ELE2 is formed of an electrode material that reflects visible light.

The electrode material that reflects visible light is not particularly limited as long as the material can reflect visible light and has electrical conductivity. Examples include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that transmits visible light is not particularly limited as long as the material can transmit visible light and has electrical conductivity. Examples include a thin film formed of a transparent metal oxide (for example, indium tin oxide, indium zinc oxide, indium gallium zinc oxide, and the like) or a metal material, such as Al, Mg, Li, and Ag.

In the example of the present embodiment described herein, the red light-emitting element including the function layer REL including the red light-emitting layer, the green light-emitting element including the function layer GEL including the green light-emitting layer, and the blue light-emitting element including the function layer BEL including the blue light-emitting layer are organic light-emitting diodes (OLEDs). However, no such limitation is intended, and these light-emitting elements may be quantum dot light-emitting diodes (QLEDs). One or more of these light-emitting elements may be OLEDs, and the rest of the light-emitting elements may be QLEDs.

The sealing layer TFE is a transparent film and, for example, may be formed of an inorganic sealing film TFE1 for covering the second electrode ELE2, an organic film TFE2 located above the inorganic sealing film TFE1, and an inorganic sealing film TFE3 located above the organic film TFE2. The sealing layer TFE inhibits substances such as water and oxygen from penetrating through to the light-emitting elements of each color.

The inorganic sealing film TFE1 and the inorganic sealing film TFE3 are both inorganic films and may be formed of, for example, a silicon oxide film, a silicon nitride film, a silicon oxynitride film, or a layered film thereof, formed by CVD. The organic film TFE2 is a transparent organic film having a flattening effect, and may be formed of a coatable organic material such as acrylic, for example. The organic film TFE2 may be formed by an ink-jet method, for example. The case has been described as an example of the present embodiment in which the sealing layer TFE is formed of two layers of an inorganic film and one layer of an organic film provided between the two layers of the inorganic film. However, the layering order of the two layers of the inorganic film and the one layer of the organic film is not limited thereto. Further, the sealing layer TFE may be formed of only an inorganic film, may be formed of only an organic film, may be formed of one layer of an inorganic film and two layers of an organic film, or may be formed of two or more layers of an inorganic film and two or more layers of an organic film.

As illustrated in FIG. 2, a drive circuit formation region GOPR including the drive circuit GDR is provided on the right side of the display region DA of the display device 1, and the drive circuit formation region GOPR including the drive circuit GDR′ is provided on the left side of the display region DA of the display device 1. In the drive circuit formation region GOPR, the plurality of transistors TRA included in the drive circuits GDR and GDR′ and a connection member CP are provided. The connection member CP provided above the flattening film JA is a member that electrically connects a power source wiring line ELVSSPL described below and the second electrode ELE2, and the connection member CP is in contact with the second electrode ELE2 in the drive circuit formation region GOPR.

As illustrated in FIG. 2, a power source wiring line formation region PHR is provided on the outer side of the drive circuit formation region GOPR of the display device 1. In the power source wiring line formation region PHR, a power source wiring line ELVSSPL, the connection member CP in contact with the power source wiring line ELVSSPL, and an inner frame-shaped bank BK1 are provided. An outer frame-shaped bank BK2 is provided at the boundary between the power source wiring line formation region PHR of the display device 1 and a sealing region TFER.

As illustrated in FIG. 2, the sealing layer TFE including the inorganic sealing film TFE1, the organic film TFE2, and the inorganic sealing film TFE3 is provided on the inner side of the inner frame-shaped bank BK1, and a sealing layer including the inorganic sealing film TFE1 and the inorganic sealing film TFE3 is provided on the outer side of the inner frame-shaped bank BK1 including above the inner frame-shaped bank BK1. The formation positions of the inner frame-shaped bank BK1 and the outer frame-shaped bank BK2 here are examples, and no such limitation is intended.

In the example of the present embodiment described herein, the crack detection wiring line CKH1 and the crack detection wiring line CKH2 are provided in the sealing region TFER. However, no such limitation is intended, and the crack detection wiring line CKH1 and the crack detection wiring line CKH2 can be provided as appropriate in the frame region NDA providing that electrical contact between the transistor TRA, the power source wiring line ELVSSPL, the connection member CP, and the second electrode ELE2 can be avoided.

In the present embodiment, the crack detection wiring line CKH1 is provided directly on the inorganic insulating film (gate insulating film) GI in the process for forming the gate electrode and the scanning line GH using the same material as the material used to form the gate electrode and the scanning line GH, and the crack detection wiring line CKH2 is provided directly on the inorganic insulating film (gate insulating film) GI in the process for forming the source electrode and the signal line SH and the drain electrode DH using the same material as the material used to form the source electrode and the signal line SH and the drain electrode DH. Since the material forming the gate electrode and the scanning line GH and the material forming the source electrode and the signal line SH and the drain electrode DH are different, the crack detection wiring line CKH1 and the crack detection wiring line CKH2 are formed of different material. Note that being provided directly on a film means being provided directly on the film and in contact with the film.

However, no such limitation is intended. For example, the crack detection wiring line CKH1 and the crack detection wiring line CKH2 may be formed in the process for forming the gate electrode and the scanning line GH using the same material as the material used to form the gate electrode and the scanning line GH, may be formed in the process for forming the source electrode and the signal line SH and the drain electrode DH using the same material as the material used to form the source electrode and the signal line SH and the drain electrode DH, may be formed in the process for forming the first electrode ELE1 using the same material as the material used to form the first electrode ELE1, or may be formed in the process for forming the second electrode ELE2 using the same material as the material used to form the second electrode ELE2.

The crack detection wiring line CKH1 and the crack detection wiring line CKH2 may be formed of the same material, may be formed of different material, may be formed directly on the same layer, or may be formed directly on different layers.

A resistance value R1 of the crack detection wiring line CKH1 is obtained via the following Formula (1).

$$R 1 = ( ρ1 \times L 1 ) / ( W 1 \times d 1 ) \qquad Formula ( 1 )$$

In Formula (1), p1 is the specific resistance value of the crack detection wiring line CKH1, L1 is the wiring line length of the crack detection wiring line CKH1, W1 is the wiring line width of the crack detection wiring line CKH1, and d1 is the film thickness of the crack detection wiring line CKH1.

A resistance value R2 of the crack detection wiring line CKH2 is obtained via the following Formula (2).

$$R 2 = ( ρ2 \times L 2 ) / ( W 2 \times d 2 ) \qquad Formula ( 2 )$$

In Formula (2), p2 is the specific resistance value of the crack detection wiring line CKH2, L2 is the wiring line length of the crack detection wiring line CKH2, W2 is the line width of the crack detection wiring line CKH2, and d2 is the film thickness of the crack detection wiring line CKH2.

A resistance value R measured via the first terminal TR1 and the second terminal TR2 forming the pair of inspection terminals is obtained via the following Formula (3) and Formula (4)

$$1 / R = ( 1 / R 1 ) + ( 1 / R 2 ) = ( R 2 + R 1 ) / ( R 1 \times R 2 ) \qquad Formula ( 3 )$$

$$R = ( R 1 \times R 2 ) / ( R 1 + R 2 ) \qquad Formula ( 4 )$$

In the present embodiment, the resistance value R1 of the crack detection wiring line CKH1 is set to a value equal to or greater than two-times the resistance value R2 of the crack detection wiring line CKH2. That is, the resistance value R1 of the crack detection wiring line CKH1 and the resistance value R2 of the crack detection wiring line CKH2 are set in a manner that the value is higher for the crack detection wiring line disposed closer to the display region DA. For example, by adjusting one or more of the specific resistance value of the crack detection wiring line CKH1, the wiring line length of the crack detection wiring line CKH1, the line width of the crack detection wiring line CKH1, the film thickness of the crack detection wiring line CKH1, the specific resistance value of the crack detection wiring line CKH2, the wiring line length of the crack detection wiring line CKH2, the line width of the crack detection wiring line CKH2, or the film thickness of the crack detection wiring line CKH2, the resistance value R1 of the crack detection wiring line CKH1 is made two-times (R1=2×R2) the resistance value R2 of the crack detection wiring line CKH2. However, no such limitation is intended, and as long as the resistance value R measured via the first terminal TR1 and the second terminal TR2 forming the pair of inspection terminals is different depending on the number of disconnections of the crack detection wiring line CKH1 and the crack detection wiring line CKH2 in the portion provided around the periphery of the display region DA, the resistance value R2 of the crack detection wiring line CKH2 may be greater than the resistance value R1 of the crack detection wiring line CKH1, or the resistance value R1 of the crack detection wiring line CKH1 and the resistance value R2 of the crack detection wiring line CKH2 may be the same.

In a case where the resistance value R1 of the crack detection wiring line CKH1 and the resistance value R2 of the crack detection wiring line CKH2 are different, the specific resistance value of the crack detection wiring line CKH1 and the specific resistance value of the crack detection wiring line CKH2 may be different by two-times or greater. In addition, the specific resistance value of the crack detection wiring line CKH1 disposed close to the display region DA may be set to a value equal to or greater than two-times the specific resistance value of the crack detection wiring line CKH2 disposed further outward. For example, the crack detection wiring line CKH1 can be formed from one or more selected from Mo (molybdenum, specific resistance: 5.6×10⁻⁸ Ω·m) and W (tungsten, specific resistance: 5.5×10⁻⁸ Ω·m) which have relatively high specific resistances, and the crack detection wiring line CKH2 can be formed of one or more selected from Al (aluminum, specific resistance: 2.75×10⁻⁸ Ω·m), Ag (silver, specific resistance: 1.62×10⁻⁸ Ω·m), and Cu (copper, specific resistance: 1.72×10⁻⁸ Ω·m) which have relatively low specific resistance.

Note that the line width of the crack detection wiring line CKH1 or the crack detection wiring line CKH2 means the substantially equal line width of the entire crack detection wiring line CKH1 or the entire crack detection wiring line CKH2, and the film thickness of the crack detection wiring line CKH1 or the crack detection wiring line CKH2 means the substantially equal film thickness of the entire crack detection wiring line CKH1 or the entire crack detection wiring line CKH2.

Since the crack detection wiring line CKH1 provided in the display devices 1, 1a, and 1b illustrated in FIGS. 1, 7, and 8 is provided near the drive circuits GDR and GDR′, it is suitable for detecting cracks deep enough to disconnect the control wiring lines in the drive circuits GDR and GDR′ such as the crack CRA and a localized crack CRD. Since the crack detection wiring line CKH2 is provided near the end portion of the sealing film TFE, it is suitable for detecting shallow cracks that damage the sealing film TFE such as the crack CRB. Note that the crack CRC which is too shallow to damage the sealing film TFE has almost no effect on the reliability of the display devices 1, 1a, and 1b and thus does not need to be detected.

Although the display devices 1, 1a, and 1b illustrated in FIGS. 1, 7, and 8 include the crack detection wiring line CKH1 and the crack detection wiring line CKH2 as the plurality of crack detection wiring lines, the first end (end on the left side at the contact point CP1 in the diagram) of each of the crack detection wiring line CKH1 and the crack detection wiring line CKH2 is electrically connected to the first terminal TR1, and the second end (end on the right side at the contact point CP2 in the diagram) of each of the crack detection wiring line CKH1 and the crack detection wiring line CKH2 is electrically connected to the second terminal TR2. Accordingly, the width of the terminal portion TRP can be prevented from being increased even without an increase in the number of inspection terminals.

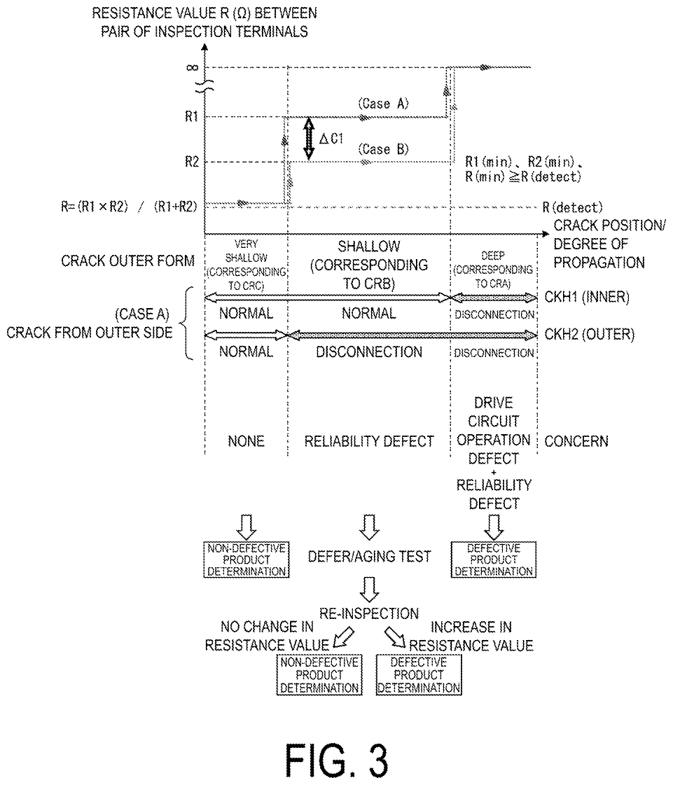

FIG. 3 is a diagram illustrating an example of an inspection method using the display devices 1, 1a, and 1b.

By applying a voltage between the first terminal TR1 and the second terminal TR2 forming the pair of inspection terminals in a parallel connection with the crack detection wiring line CKH1 and the crack detection wiring line CKH2, the resistance value between the first terminal TR1 and the second terminal TR2 can be measured. The resistance value stepwisely changes depending on how the crack is formed and the propagation propensity, and thus how much the crack has propagated can be deduced.

The inspection method illustrated in FIG. 3 is a simple inspection method that can detect whether or not a crack, such as the crack CRA, with propagation propensity from the panel outer form has reached the drive circuit (whether or not a crack has a fatal effect on the drive circuit operation). This will be described below.

The inspection method illustrated in FIG. 3 has an advantage in that there is a discernible resistance value clearance between the resistance value R1 (CKH1 in a non-disconnected state) and a resistance value derived from either the resistance value R2 (CKH2 in a non-disconnected state) or the combined wiring line resistance value R (substantially both CKH1 and CKH2 in a non-disconnected state) and in that there is also a discernible resistance value clearance between the resistance value R1 (CKH1 in a non-disconnected state) and a resistance value œ (both CKH1 and CKH2 in a disconnected state). Thus, it is possible to discern whether the crack detection wiring line CKH1 is disconnected or not, and it is possible to determine whether a crack from the panel outer form has reached CKH1 (the drive circuit) as in the case of the crack CRA.

The inspection method illustrated in FIG. 3 can be suitably used in a case where variation in the resistance value measured by the first terminal TR1 and the second terminal TR2 is relatively large, a clearly discernible resistance value clearance cannot be ensured between the resistance value R2 (only CKH1 in a disconnected state due to the localized crack CRD (case B)) and the combined wiring line resistance value R(CKH1 and CKH2 in a non-disconnected state due to there being no cracks or a crack being very shallow (corresponding to the case of the crack CRC)), and it may not be able to be discerned whether the resistance value measured via the first terminal TR1 and the second terminal TR2 is derived from the resistance value R2 (localized crack CRD) or derived from the combined wiring line resistance value R (no crack or very shallow crack).

In the inspection method illustrated in FIG. 3, it is not expected that the localized crack CRD is detected by the display devices 1, 1a, and 1b illustrated in FIGS. 1, 7, and 8. Thus, in a case where a resistance value less than the resistance value R1 (only CKH2 in a disconnected state and CKH1 in a non-disconnected state (case A)), whether the very shallow crack CRC has formed (CKH2 in a non-disconnected state) or a crack has not formed (CKH1 and CKH2 in a non-disconnected state) is deduced. That is, the inspection method illustrated in FIG. 3 can be suitably used to deduce how much a crack from the panel outer form has propagated.

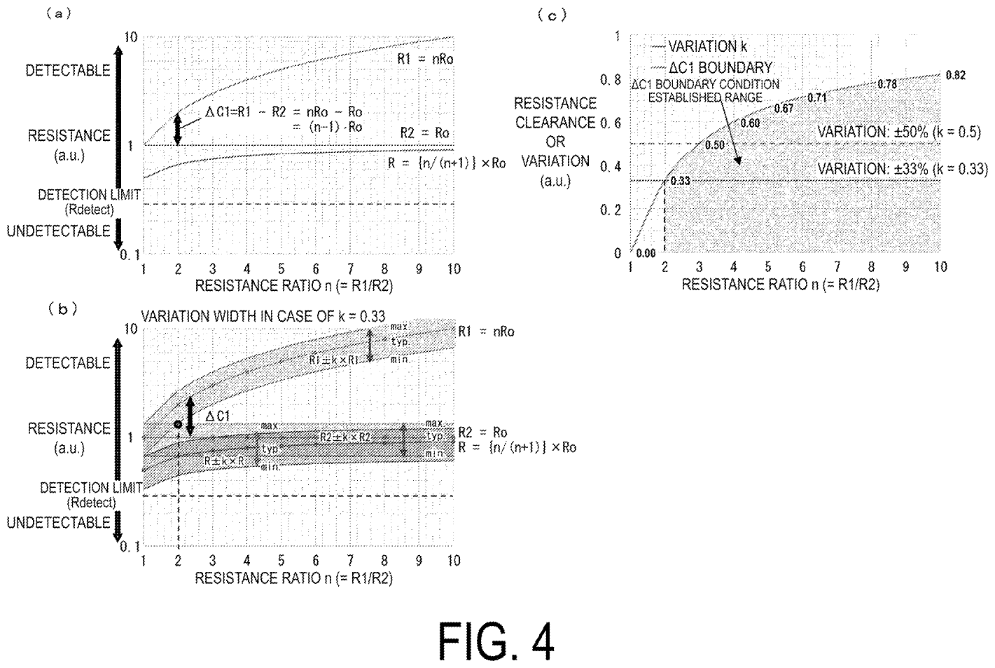

(a), (b), and (c) of FIG. 4 are diagrams showing the relationship, when designing the crack detection wiring line for implementing an inspection method using the display device according to the first embodiment illustrated in FIG. 3, between a resistance ratio n (=R1/R2) of the resistance value R1 of the crack detection wiring line CKH1 and the resistance value R2 of the crack detection wiring line CKH2, the resistance values at this time, and the resistance value variation and are diagrams for describing the resistance ratio n (=R1/R2) and the variation (±k) that are preferable in terms of design.

In order to realize the inspection method using the display device according to the first embodiment illustrated in FIG. 3, the following two conditions, condition (1) and condition (2), must be satisfied.

Condition (1): a minimum value R1 (min) of the resistance value R1 of the crack detection wiring line CKH1, a minimum value R2 (min) of the resistance value R2 of the crack detection wiring line CKH2, and a minimum value R (min) of the combined wiring line resistance value R are all equal to or greater than a detection threshold R (detect) of the detectable resistance value (R1 (min), R2 (min), R (min)≥R (detect)).

Condition (2): the resistance value measured via the first terminal TR1 and the second terminal TR2 forming the pair of inspection terminals can be discerned to be a resistance value derived from the resistance value R1 (only CKH2 in a disconnected state and CKH1 in a non-disconnected state (case A)) or a resistance value (substantially both CKH1 and CKH2 are in a non-disconnected state) derived from the indiscernible resistance value R2 and the combined wiring line resistance value R, that is, there is a clearly discernible resistance value clearance (AC1) between the resistance value R2, the higher of the resistance value R2 and the combined wiring line resistance value R, and the resistance value R1.

(a) of FIG. 4 is a graph showing calculations of how the resistance value R1, the resistance value R2 and the combined wiring line resistance value R change depending on the resistance ratio n of the resistance value R1 and the resistance value R2. Here, assuming that the resistance value of the crack detection wiring line CKH2 is R2=Ro and the resistance value of the crack detection wiring line CKH1 is R1=n×R2=n×Ro, the combined wiring line resistance value R of the crack detection wiring line CKH1 and the crack detection wiring line CKH2 measured via the first terminal TR1 and the second terminal TR2 forming the pair of inspection terminals is expressed by R=(R1×R2)/(R1+R2)={n/(n+1)}×Ro.

(b) of FIG. 4 is the graph shown in (a) of FIG. 4 when taking into account a resistance value variation (k=0.33). Since there is a variation (+k times) in the actual resistance value, the resistance value R1 of the crack detection wiring line CKH1, the resistance value R2 of the crack detection wiring line CKH2, and the combined wiring line resistance value R are expressed by R1 #k×R1=(1+k)×nRo, R2+k×R2=(1+k)×Ro, and R=k×R=(1+k)×{n/(n+1)}×Ro, respectively, and have the relationship shown in (b) of FIG. 4. As shown in (b) of FIG. 4, if there is variation in each resistance value but the two conditions, condition (1) and condition (2) described above, are satisfied, the resistance value measured via the first terminal TR1 and the second terminal TR2 can be discerned to be a resistance value derived from any one of a first state to a third state described below. Three states can be discerned, namely a first state with a resistance value (corresponding to co or corresponding to a very high resistance equal to or greater than 10 MΩ (not illustrated)) due to both CKH1 and CKH2 being disconnected by the crack CRA from the outer side, a second state with a resistance value (case A) derived from the resistance value R1 due to only the CKH2 being disconnected by the crack CRB from the outer side, and a third state with a resistance value (only CKH1 in a disconnected state or both CKH1 and CKH2 being in a non-disconnected state, that is, at least CKH2 is in a non-disconnected state) derived from the indiscernible resistance value R2 and the combined wiring line resistance value R. As illustrated in FIG. 3 and shown in (a) and (b) of FIG. 4, the combined wiring line resistance value R is always even lower than the lower resistance value R2. Thus, looking at the relationship between the resistance value R1 and the resistance value R2 is sufficient, and the relationship between the resistance value R1 and the combined wiring line resistance value R does not need to be looked at.

As shown in (a) and (b) of FIG. 4, assuming the typ. value difference (clearance) of the resistance value R1 and the resistance value R2 is ΔC1, ΔC1=R1−R2=n×Ro−Ro=(n−1)×Ro is satisfied. For there to be a clearly discernible resistance value clearance between the resistance value R1 and the resistance value R2, clearance ΔC1>(R1 variation)+ (R2 variation) must be satisfied.

$$\begin{matrix}Δ C 1 > k \times R 1 + k \times R 2 \\ ( n - 1 ) \times Ro > k \times nRo + k \times Ro \\ ( n - 1 ) / ( n + 1 ) > k\end{matrix} \qquad Formula ( A ) : ΔC1 boundary condition$$

Thus, the above-described condition (2) is satisfied when the variation width k satisfies the above-described Formula (A) (when the variation width k is less than the AC1 boundary).

As shown in (c) of FIG. 4, for example, if the resistance value variation is assumed to be about ±33% (k=0.33), n=2 when k=0.33 according to the above-described Formula (A). That is, by setting the resistance ratio n=R1/R2 of the resistance value R1 of the crack detection wiring line CKH1 and the resistance value R2 of the crack detection wiring line CKH2 to 2 or greater as in the present embodiment, even if there is a variation in the resistance value of about ±33%, the resistance value measured via the first terminal TR1 and the second terminal TR2 can be discerned to be a resistance value derived from the resistance value R1 or a resistance value derived from the indiscernible resistance value R2 and the combined wiring line resistance value R. When the horizontal axis of the graph shown in (c) of FIG. 4 is the resistance ratio n of the resistance value R1 and the resistance value R2 and the vertical axis is the clearance or variation relative ratio, the region (the colored-in region) where the straight line of the variation k is below the ΔC1 boundary is a condition range (ΔC1 boundary condition established range) in which the resistance value R1 and the resistance value R2 or the combined wiring line resistance value R can be discerned from one another. As shown in (c) of FIG. 4, for example, when k=0.33, n=2, and when k=0.5, and n=3. Accordingly, in the case of variation width k=0.33, by using a layout in which the resistance ratio n (=R1/R2) of the resistance value R1 of the crack detection wiring line CKH1 and the resistance value R2 of the crack detection wiring line CKH2 is 2 or greater, the resistance value can be discerned, and whether a crack from the panel outer form has reached CKH1 (the drive circuit) can be deduced. Also, it can be seen from (c) of FIG. 4 that when the resistance value variation increases, the resistance ratio n of the resistance value R1 and the resistance value R2 must be increased. Thus, it is desirable that the resistance ratio n (=R1/R2) of the resistance value R1 of the crack detection wiring line CKH1 and the resistance value R2 of the crack detection wiring line CKH2 is 2 or greater.

Accordingly, when the variation width k and the resistance ratio n (n=R1/R2) of the resistance value R1 of the crack detection wiring line CKH1 and the resistance value R2 of the crack detection wiring line CKH2 satisfy Formula (A), with the present inspection method, whether the resistance value measured via the first terminal TR1 and the second terminal TR2 is a resistance value derived from the resistance value R1 or a resistance value derived from the indiscernible resistance value R2 and the combined wiring line resistance value R can be discerned. Thus, whether a crack from the panel outer form has reached CKH1 (the drive circuit) can be deduced via discerning between the measured resistance values. Since it is possible to determine a non-defective product or a defective product in accordance with the degree of propagation, it is possible to save panels without a fatal problem and thus improve the yield. At this time, it is desirable that a layout is used in which the resistance ratio n (=R1/R2) of the resistance value R1 of the crack detection wiring line CKH1 and the resistance value R2 of the crack detection wiring line CKH2 is 2 or greater.

In the display devices 1, 1a, and 1b illustrated in FIGS. 1, 7, and 8, in the case of a crack such as the crack CRC forming that is too shallow to damage the sealing film TFE, is not significant enough to effect the reliability of the display devices 1, 1a, and 1b, and does not give rise to reliability concerns, as illustrated in FIG. 3, both the crack detection wiring line CKH1 and the crack detection wiring line CKH2 are not disconnected and the display devices 1, 1a, and 1b function normally. Thus, in such a case, the resistance value measured via the first terminal TR1 and the second terminal TR2 forming the pair of inspection terminals corresponds to the combined wiring line resistance value R of the crack detection wiring lines CKH1 and CKH2, that is R=(R1×R2)/(R1+R2). Here, R1 is the resistance value of the crack detection wiring line CKH1, and R2 is the resistance value of the crack detection wiring line CKH2. Thus, in the present embodiment, since the resistance value R1 of the crack detection wiring line CKH1 is two-times (R1=2×R2=2×Ro) the resistance value R2 of the crack detection wiring line CKH2, in a case where, as the resistance value, (R1×R2)/(R1+R2)=(1/3)R1=(2/3)R2=(2/3)Ro is obtained, the degree of propagation of the crack of the display devices 1, 1a, and 1b is very shallow or no cracks are formed. This allows a non-defective product determination to be made.

At this time, with the inspection method illustrated in FIG. 3, as described above, it is not assumed that the localized crack CRD will be detected. Thus, as described above, in a case where the resistance value measured via the first terminal TR1 and the second terminal TR2 forming the pair of inspection terminals is measured to be a resistance value (for example, (1/3)R1) less than the resistance value R1 (only CKH2 is in a disconnected state and CKH1 is in a non-disconnected state (case A)), it is determined that there is no localized crack CRD and that the very shallow crack CRC has formed or there are no cracks.

Further, in a case where the shallow crack CRB that can damage a portion of the sealing film TFE has formed in the display devices 1, 1a, and 1b illustrated in FIGS. 1, 7, and 8, there are reliability defect concerns due to the crack damaging the sealing film TFE. When a crack such as the crack CRB is formed, as illustrated in FIG. 3, the crack detection wiring line CKH1 is normal, and the crack detection wiring line CKH2 is disconnected. Thus, in such a case, in a first crack detection process, the resistance value measured via the first terminal TR1 and the second terminal TR2 forming the pair of inspection terminals corresponds to the resistance value R1 of the normal crack detection wiring line CKH1. In a case where the resistance value R1 of the crack detection wiring line CKH1 is obtained to be the resistance value, the degree of crack propagation of the display devices 1, 1a, and 1b is shallow. Thus, non-defective product determination and defective product determination are deferred, and an aging test of a predetermined amount of time is performed using the display devices 1, 1a, and 1b for which determination has been deferred. The aging test means a process of causing the display devices 1, 1a, and 1b to perform a lighting operation in predetermined temperature and humidity conditions, for example, for a predetermined amount of time. Thereafter, in a re-inspection process (second crack detection process), the resistance value is measured again via the first terminal TR1 and the second terminal TR2 forming the pair of inspection terminals for the display devices 1, 1a, and 1b after the aging test has been performed for a predetermined amount of time. By comparing the resistance value obtained in the first crack detection process with the resistance value obtained in the re-inspection process (second crack detection process), it is possible to detect any change in the crack that occurs during the aging test of the predetermined amount of time. If there is no change between the resistance value obtained in the first crack detection process and the resistance value obtained in the re-inspection process (second crack detection process), the formed crack CRB is a crack without propagation propensity, and the display devices 1, 1a, and 1b can be determined to be a non-defective product. On the other hand, if the resistance value obtained in the re-inspection process (second crack detection process) is greater than the resistance value obtained in the first crack detection process, the formed crack CRB is determined to be a crack with propagation propensity, and the display devices 1, 1a, and 1b can be determined to be a defective product.

In addition, in a case where the deep crack CRA which can disconnect the control wiring line in the drive circuits GDR and GDR′ is formed in the display devices 1, 1a, and 1b illustrated in FIGS. 1, 7, and 8, there is a drive circuit operation defect concern and a reliability defect concern due to the crack being able to damage the sealing film TFE. When a crack such as the crack CRA is formed, as illustrated in FIG. 3, the crack detection wiring line CKH1 and the crack detection wiring line CKH2 are both disconnected. Thus, in such a case, the resistance value measured via the first terminal TR1 and the second terminal TR2 forming the pair of inspection terminals corresponds to ∞ (for example, 10 MΩ or greater). Thus, in a case where ∞ (for example, 10 M (2 or greater) is obtained to be the resistance value, the degree of crack propagation of the display devices 1, 1a, and 1b is deep, and thus a defective product determination can be made.

As described above, according to the display devices 1, 1a, and 1b and the inspection method using the display devices 1, 1a, and 1b, improved yield (non-defect rate) and reduced manufacturing costs can be achieved.

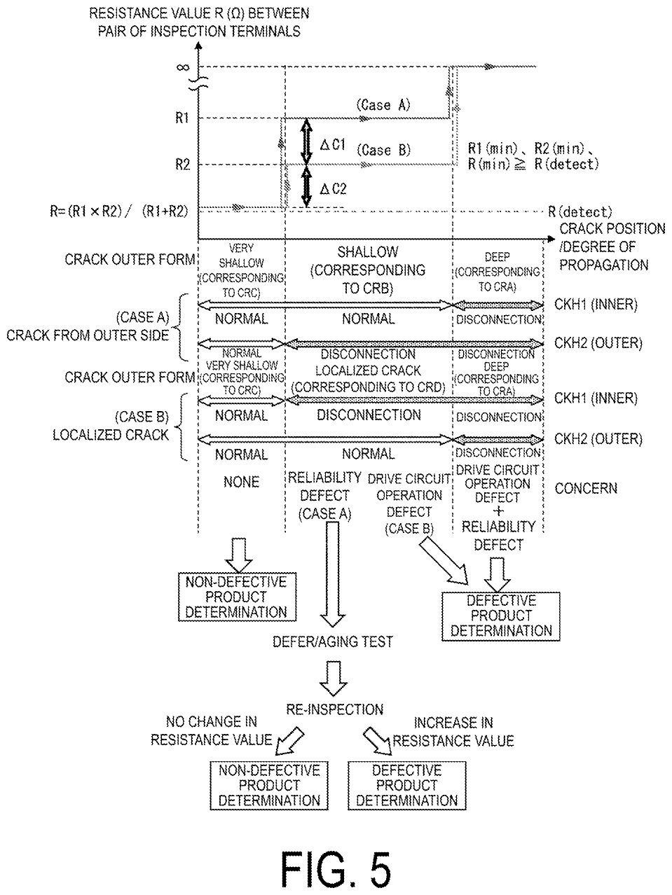

FIG. 5 is a diagram illustrating another example of an inspection method using the display devices 1, 1a, and 1b.

According to the inspection method illustrated in FIG. 5, not only can a crack, such as the crack CRA, from the panel outer form with propagation propensity be inspected, but a crack, such as the localized crack CRD, that can disconnect only the crack detection wiring line CKH1 provided near the drive circuits GDR and GDR′ can also be inspected.

The inspection method illustrated in FIG. 5 has an advantage in that, in addition to that of the inspection method of FIG. 3, there is a clear resistance value clearance between the resistance value R2 (only CKH1 in a disconnected state) and the combined wiring line resistance value R (both CKH1 and CKH2 in a non-disconnected state). As in the inspection method illustrated in FIG. 3, there is an advantage in that there is a discernible resistance value clearance between the resistance value R1 (CKH1 in a non-disconnected state) and the resistance value R2 (only CKH1 in a disconnected state) and in that there is also a discernible resistance value clearance between the resistance value R1 (CKH1 in a non-disconnected state) and a resistance value ∞ (both CKH1 and CKH2 in a disconnected state). Thus, it is possible to discern whether the crack detection wiring lines CKH1 and CKH2 are disconnected or not, and it is possible to discern whether a crack reaching the drive circuit is caused by a crack from the panel outer form with propagation propensity or by a localized crack.

The inspection method illustrated in FIG. 5 can be suitably used in a case where variation in the resistance value measured by the first terminal TR1 and the second terminal TR2 is relatively small, and a clearly discernible resistance value clearance can be ensured between the resistance value R2 (only CKH1 in a disconnected state due to the localized crack CRD (case B)) and the combined wiring line resistance value R (no cracks or the crack is very shallow).

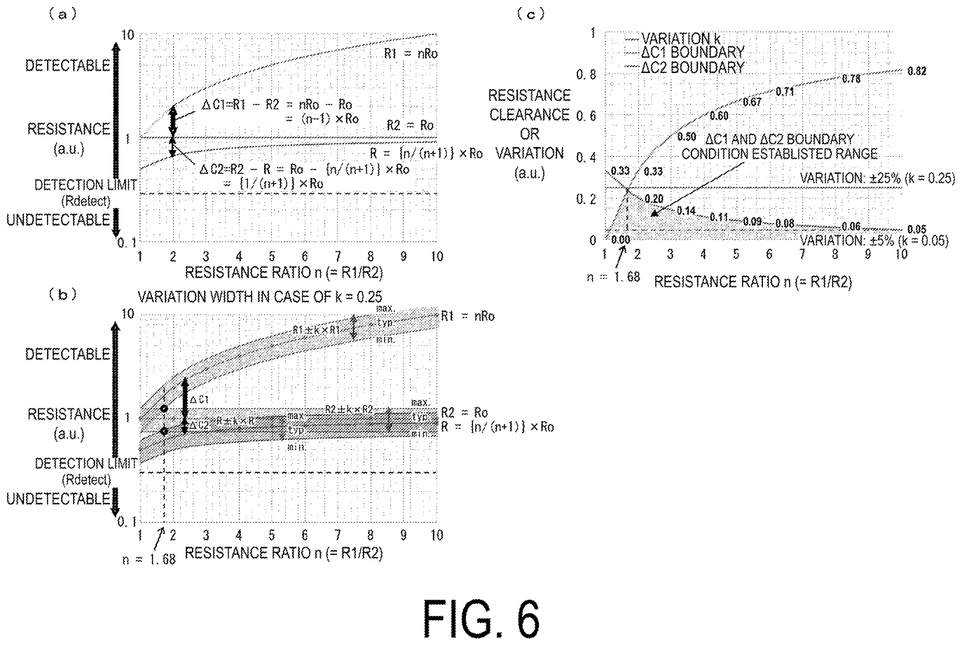

(a), (b), and (c) of FIG. 6 are diagrams for describing the preferable resistance ratio n (=R1/R2) of the resistance value R1 of the crack detection wiring line CKH1 and the resistance value R2 of the crack detection wiring line CKH2 due to the variation in resistance value measured according to another example of the inspection method using the display device of the first embodiment illustrated in FIG. 5.

In order to realize the inspection method illustrated in FIG. 5, the following two conditions, condition (3) and condition (4), must be satisfied.

Condition (3): a minimum value R1 (min) of the resistance value R1 of the crack detection wiring line CKH1, a minimum value R2 (min) of the resistance value R2 of the crack detection wiring line CKH2, and a minimum value R (min) of the combined wiring line resistance value R are all equal to or greater than a detection threshold R (detect) of the detectable resistance value (R1 (min), R2 (min), R (min)≥R (detect)).

Condition (4): the resistance value measured via the first terminal TR1 and the second terminal TR2 forming the pair of inspection terminals can be discerned to be a resistance value derived from the resistance value R1 (only CKH2 is in a disconnected state (case A) due to the crack CRB from the outer side), a resistance value derived from the resistance value R2 (only CKH1 is in a disconnected state (case B) due to the localized crack CRD), or a resistance value derived from the combined wiring line resistance value R (both CKH1 and CKH2 are in a non-disconnected state), that is, there is a clearly discernible resistance value clearance (ΔC1) between the resistance value R2 and the resistance value R1 and a clearly discernible resistance value clearance (AC2) between the resistance value R2 and the combined wiring line resistance value R.

(a) of FIG. 6 is a graph showing calculations of how the resistance value R1, the resistance value R2 and the combined wiring line resistance value R change depending on the resistance ratio n of the resistance value R1 and the resistance value R2. Here, assuming that the resistance value of the crack detection wiring line CKH2 is R2=Ro and the resistance value of the crack detection wiring line CKH1 is R1=n×R2=n×Ro, the combined wiring line resistance value R of the crack detection wiring line CKH1 and the crack detection wiring line CKH2 measured via the first terminal TR1 and the second terminal TR2 forming the pair of inspection terminals is expressed by R=(R1×R2)/(R1+R2)={n/(n+1)}×Ro.

(b) of FIG. 6 is the graph shown in (a) of FIG. 6 when taking into account a resistance value variation (k=0.25). Since there is a variation (+k times) in the actual resistance value, the resistance value R1 of the crack detection wiring line CKH1, the resistance value R2 of the crack detection wiring line CKH2, and the combined wiring line resistance value R are expressed by R1+k×R1=(1+k)×nRo, R2+k×R2=(1+k)×Ro, and R=k×R=(1+k)×{n/(n+1)}×Ro, respectively, and have the relationship shown in (b) of FIG. 6. As shown in (b) of FIG. 6, if there is variation in each resistance value but the two conditions, condition (3) and condition (4) described above, are satisfied, the resistance value measured via the first terminal TR1 and the second terminal TR2 can be discerned to be a resistance value derived from any one of a first state to a fourth state described below. Four states can be discerned, namely a first state with a resistance value (corresponding to co or corresponding to a very high resistance equal to or greater than 10 MΩ (not illustrated)) due to both CKH1 and CKH2 being disconnected by the crack CRA from the outer side, a second state with a resistance value (case A) derived from the resistance value R1 due to only the CKH2 being disconnected by the crack CRB from the outer side, a third state with a resistance value (case B) derived from the resistance value R2 due to only CKH1 being disconnected by the localized crack CRD, and a fourth state with a resistance value derived from the combined wiring line resistance value R due to both CKH1 and CKH2 being not disconnected.

As shown in (a) and (b) of FIG. 6, assuming the typ. value difference (clearance) of the resistance value R1 and the resistance value R2 is ΔC1, ΔC1=R1−R2=n×Ro−Ro=(n−1)×Ro is satisfied, and assuming the typ. value difference (clearance) of the resistance value R2 and the combined wiring line resistance value R is ΔC2, ΔC2=R2−R=Ro−{n/(n+1)}×Ro={1/(n+1)}×Ro is satisfied. For there to be a clearly discernible resistance value clearance between the resistance value R1 and the resistance value R2, clearance ΔC1>(R1 variation)+ (R2 variation) must be satisfied. Thus, the variation width k needs to satisfy the following Formula (B).

$$\begin{matrix}Δ C 1 > k \times R 1 + k \times R 2 \\ ( n - 1 ) \times Ro > k \times nRo + k \times Ro \\ ( n - 1 ) / ( n + 1 ) > k\end{matrix} \qquad Formula ( B ) : ΔC1 boundary condition$$

In a similar manner, for there to be a clearly discernible resistance value clearance between the resistance value R2 and the combined wiring line resistance value R, clearance ΔC2>(R2 variation)+ (R variation) must be satisfied. Thus, the variation width k also needs to satisfy the following Formula (C).

$$\begin{matrix}Δ C 2 > k \times R 2 + k \times R \\ \{ 1 / ( n + 1 ) \} \times Ro > k \times Ro + k \times \{ n / ( n + 1 ) \} \times Ro \\ \{ 1 / ( n + 1 ) \} > \{ ( 2 n + 1 ) / ( n + 1 ) \} \\ 1 / ( 2 n + 1 ) > k\end{matrix} \qquad Formula ( C ) : ΔC2 boundary condition$$

Accordingly, when the variation width k satisfies the above-described Formula (B) and the above-described Formula (C) (when the variation width k is less than both the ΔC1 boundary condition and the ΔC2 boundary condition), the above-described condition (4) is satisfied.

Solving the simultaneous equations (B) and (C) yields n=1.68 and k=0.25.

That is, as shown in (c) of FIG. 6, the curve of the ΔC1 boundary condition represented by Formula (B) and the curve of the ΔC2 boundary condition represented by Formula (C) share an intersection point at k=0.25 (resistance value variation of about +25%) when the resistance ratio n=1.68. That is, by setting the resistance ratio n=R1/R2 of the resistance value R1 of the crack detection wiring line CKH1 and the resistance value R2 of the crack detection wiring line CKH2 to 1.68, even if there is a variation in the resistance value of about +25%, the resistance value measured via the first terminal TR1 and the second terminal TR2 can be discerned to be a resistance value derived from the resistance value R1, a resistance value derived from the resistance value R2, or a resistance value derived from the combined wiring line resistance value R.

Thus, it is most desirable that the resistance ratio n (=R1/R2) of the resistance value R1 of the crack detection wiring line CKH1 and the resistance value R2 of the crack detection wiring line CKH2 is 1.68.

In the present embodiment, as described above, for example, by setting the resistance ratio n=(R1/R2) of the resistance value R1 of the crack detection wiring line CKH1 and the resistance value R2 of the crack detection wiring line CKH2 to 2, even if the tolerable resistance value variation decreases to k=0.2 (corresponding to +20%) and there is a variation of about +20% in each resistance value, the resistance value measured via the first terminal TR1 and the second terminal TR2 forming a pair of inspection terminals can be discerned to be a resistance value derived from the resistance value R1 (crack from the outer side (case A)), a resistance value derived from the resistance value R2 (localized crack (case B)), or a resistance value derived from the combined wiring line resistance value R.

In a case where the resistance ratio n (=R1/R2) of the resistance value R1 of the crack detection wiring line CKH1 and the resistance value R2 of the crack detection wiring line CKH2 is 1.68, for example, by forming the crack detection wiring line CKH1 and the crack detection wiring line CKH2 of the same material, the specific resistance value of the crack detection wiring line CKH1 and the specific resistance value of the crack detection wiring line CKH2 may be made the same, the line width of the crack detection wiring line CKH1 and the line width of the crack detection wiring line CKH2 may be made the same, and the film thickness of the crack detection wiring line CKH1 and the film thickness of the crack detection wiring line CKH2 may be made the same, but the length of the crack detection wiring line CKH1 may be made 1.68 times longer than the length of the crack detection wiring line CKH2.

When the horizontal axis of the graph shown in (c) of FIG. 6 is the resistance ratio n of the resistance value R1 and the resistance value R2 and the vertical axis is the clearance or variation relative ratio, the region (the colored-in region) below both the AC1 boundary and the ΔC2 boundary is a condition range (ΔC1 and ΔC2 boundary condition established range) in which the resistance value R1, the resistance value R2, and the combined wiring line resistance value R can be discerned. Thus, when the resistance ratio n (=R1/R2) is set to about 1.68, the variation k can take the maximum value (k=0.25). Thus, in order to make a design in which the resistance value variation is allowed to the maximum, the resistance ratio n (=R1/R2) is most preferably set to about 1.68. In addition, as shown in (c) of FIG. 6, for example, in a case where the resistance value variation can be suppressed to k=0.05, n can take a wide range of 1.1<n<10, and thus giving the setting of n a high degree of flexibility. That is, when the variation in each resistance values decreases, the degree of freedom of design relating to the resistance ratio n (=R1/R2) of the resistance value R1 of the crack detection wiring line CKH1 and the resistance value R2 of the crack detection wiring line CKH2 increases, and the present inspection method becomes easier to realize. Thus, the inspection method can be suitably used when the resistance value variation measured via the first terminal TR1 and the second terminal TR2 is relatively small.

According to the inspection method illustrated in FIG. 5, not only can cracks from the outer side, such as the very shallow crack CRC, the shallow crack CRB, and the deep crack CRA, be inspected, but a crack, such as the localized crack CRD, that can disconnect only the crack detection wiring line CKH1 provided near the drive circuits GDR and GDR′ can also be inspected.

In the display devices 1, 1a, and 1b illustrated in FIGS. 1, 7, and 8, regarding the case of a crack such as the crack CRC forming that is too shallow to damage the sealing film TFE, is not significant enough to effect the reliability of the display device, and does not give rise to reliability concerns, as illustrated in FIG. 5, matters are the same as that described above on the basis of FIG. 3 and thus will not be described here.

Also, in the display devices 1, 1a, and 1b illustrated in FIGS. 1, 7, and 8, regarding the case of the shallow crack CRB that can damage a portion of the sealing film TFE being formed, as illustrated in FIG. 5, matters are the same as that described above on the basis of FIG. 3 and thus will not be described here.

Also, in the display devices 1, 1a, and 1b illustrated in FIGS. 1, 7, and 8, regarding the case of the crack CRA deep enough to disconnect the control wiring line in the drive circuits GDR and GDR′, as illustrated in FIG. 5, matters are the same as that described above on the basis of FIG. 3 and thus will not be described here.

In addition, in a case where the localized crack CRD that can disconnect only the crack detection wiring line CKH1 provided near the drive circuits GDR and GDR′ is formed in the display devices 1, 1a, and 1b illustrated in FIGS. 1, 7, and 8, there is a drive circuit operation defect concern. When a crack such as the localized crack CRD is formed, as illustrated in FIG. 5, the crack detection wiring line CKH1 is disconnected, and the crack detection wiring line CKH2 is normal. Thus, in such a case, the resistance value measured via the first terminal TR1 and the second terminal TR2 forming the pair of inspection terminals corresponds to the resistance value R2 of the crack detection wiring line CKH2. This case is handled in a similar manner to the case of the deep crack CRA forming, and the aging test and the re-inspection process (second crack detection process) are not performed on the display devices 1, 1a, and 1b and a defective product determination is made. Alternatively, this case may be handled in a similar manner to the case of the shallow crack CRB that can damage a portion of the sealing film TFE, and the non-defective product determination and the defective product determination of the display devices 1, 1a, and 1b may be deferred, and the aging test of a predetermined amount of time may be performed using the display devices 1, 1a, and 1b for which determination has been deferred. Thereafter, the re-inspection process (second crack detection process) described above may be performed and a non-defective product determination or a defective product determination may be made.

As described above, according to the display devices 1, 1a, and 1b illustrated in FIGS. 1, 7, and 8 and the inspection method illustrated in FIGS. 5 and 6 using the display devices 1, 1a, and 1b illustrated in FIGS. 1, 7, and 8, an inspection of localized cracks can be performed and a non-defective product/defective product determination can be made according to the detected resistance value. This allows panels without a fatal problem to be saved, and yield to be improved.

As described above, in the example of the present embodiment described above, the display devices 1, 1a, and 1b are provided with light-emitting elements such as OLEDs, QLEDs, or the like. However, no such limitation is intended, and the display devices 1, 1a, and 1b may be a reflective liquid crystal display device without a backlight or a liquid crystal display device with a backlight, for example.

### Second Embodiment

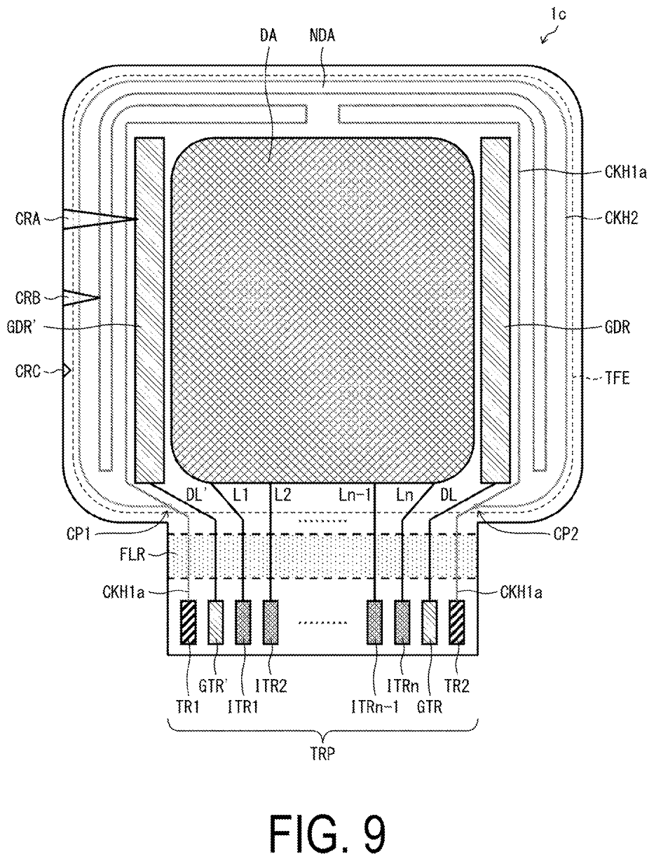

Next, with reference to FIG. 9, a second embodiment of the disclosure will be described. A display device 1c of the present embodiment is different from that of the first embodiment in that the length of a crack detection wiring line CKH1a disposed closer to the display region DA than the crack detection wiring line CKH2 is equal to or greater than two-times the length of the crack detection wiring line CKH2. The others are as described in the first embodiment. For convenience of description, members having the same functions as those illustrated in diagrams of the first embodiment are denoted by the same reference signs, and descriptions thereof are omitted.

FIG. 9 is a schematic plan view illustrating a configuration of the display device 1c according to the second embodiment.

As illustrated in FIG. 9, in the display device 1c, the length of the crack detection wiring line CKH1a disposed closer to the display region DA than the crack detection wiring line CKH2 is equal to or greater than two-times the length of the crack detection wiring line CKH2.

In the present embodiment, the crack detection wiring line CKH1a and the crack detection wiring line CKH2 are formed of the same material. Thus, the specific resistance value of the crack detection wiring line CKH1a and the specific resistance value of the crack detection wiring line CKH2 are the same. Also, the line width of the crack detection wiring line CKH1a and the line width of the crack detection wiring line CKH2 are the same, and the film thickness of the crack detection wiring line CKH1a and the film thickness of the crack detection wiring line CKH2 are the same. By setting the wiring line length of the crack detection wiring line CKH1a to two-times the wiring line length of the crack detection wiring line CKH2, the resistance value R1 of the crack detection wiring line CKH1a is set to two-times the resistance value R2 of the crack detection wiring line CKH2 (R1=2×R2). However, no such limitation is intended.

As described above, in the example of the present embodiment described above, the plurality of crack detection wiring lines include two wiring lines, the crack detection wiring line CKH1a and the crack detection wiring line CKH2 and the length of the crack detection wiring line CKH1a is equal to or greater than two-times the length of the crack detection wiring line CKH2. However, no such limitation is intended, and with two of the plurality of crack detection wiring lines, the length of one of the crack detection wiring lines may be different from the length of the other crack detection wiring line by two-times or greater.

According to the display device 1c and the inspection method using the display device 1c, improved yield (non-defect rate) and reduced manufacturing costs can be achieved and non-illustrated localized crack inspection can also be performed.

### Third Embodiment

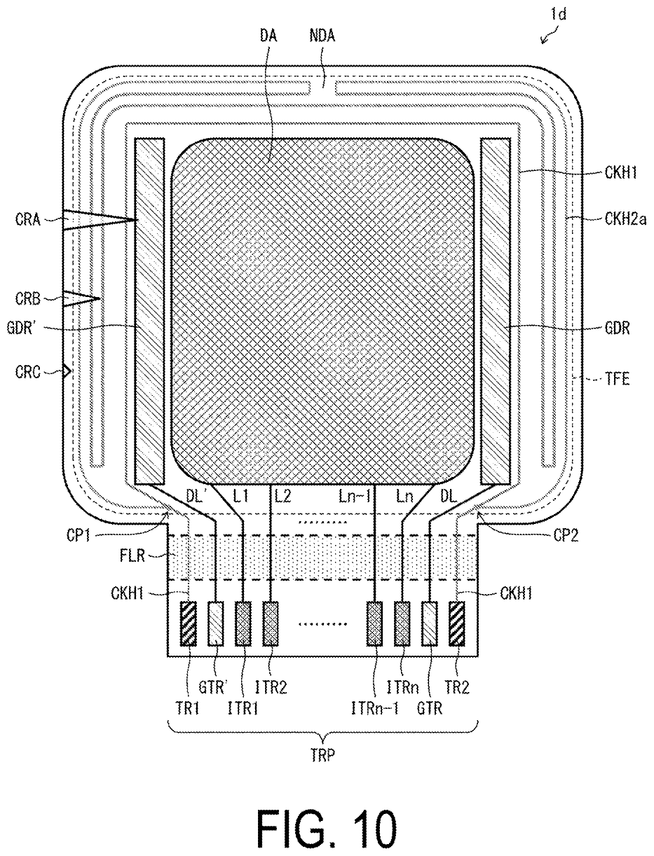

Next, a third embodiment according to the disclosure will be described with reference to FIG. 10. A display device 1d of the present embodiment is different from that of the first and second embodiment in that the length of a crack detection wiring line CKH2a is equal to or greater than two-times the length of the crack detection wiring line CKH1 disposed closer to the display region DA than the crack detection wiring line CKH2a. The others are as described in the first and second embodiments. For convenience of description, members having the same functions as the members illustrated in the diagrams in the first and second embodiments are denoted by the same reference signs, and descriptions thereof will be omitted.

FIG. 10 is a schematic plan view illustrating a configuration of the display device 1d according to the third embodiment.

As illustrated in FIG. 10, in the display device 1d, the length of the crack detection wiring line CKH2a is equal to or greater than two-times the length of the crack detection wiring line CKH1 disposed closer to the display region DA than the crack detection wiring line CKH2a.

In the present embodiment, the crack detection wiring line CKH1 and the crack detection wiring line CKH2a are formed of the same material. Thus, the specific resistance value of the crack detection wiring line CKH1 and the specific resistance value of the crack detection wiring line CKH2a are the same. Also, the line width of the crack detection wiring line CKH1 and the line width of the crack detection wiring line CKH2a are the same, and the film thickness of the crack detection wiring line CKH1 and the film thickness of the crack detection wiring line CKH2a are the same. By setting the wiring line length of the crack detection wiring line CKH2a to two-times the wiring line length of the crack detection wiring line CKH1, the resistance value R2 of the crack detection wiring line CKH2a is set to two-times the resistance value R1 of the crack detection wiring line CKH1 (R2=2×R1). However, no such limitation is intended.

As described above, in the example of the present embodiment described above, the plurality of crack detection wiring lines include two wiring lines, the crack detection wiring line CKH1 and the crack detection wiring line CKH2a, and the length of the crack detection wiring line CKH2a is equal to or greater than two-times the length of the crack detection wiring line CKH1. However, no such limitation is intended, and with two of the plurality of crack detection wiring lines, the length of one of the crack detection wiring lines may be different from the length of the other crack detection wiring line by two-times or greater.

According to the display device 1d and the inspection method using the display device 1d, improved yield (non-defect rate) and reduced manufacturing costs can be achieved and non-illustrated localized crack inspection can also be performed.

### Fourth Embodiment

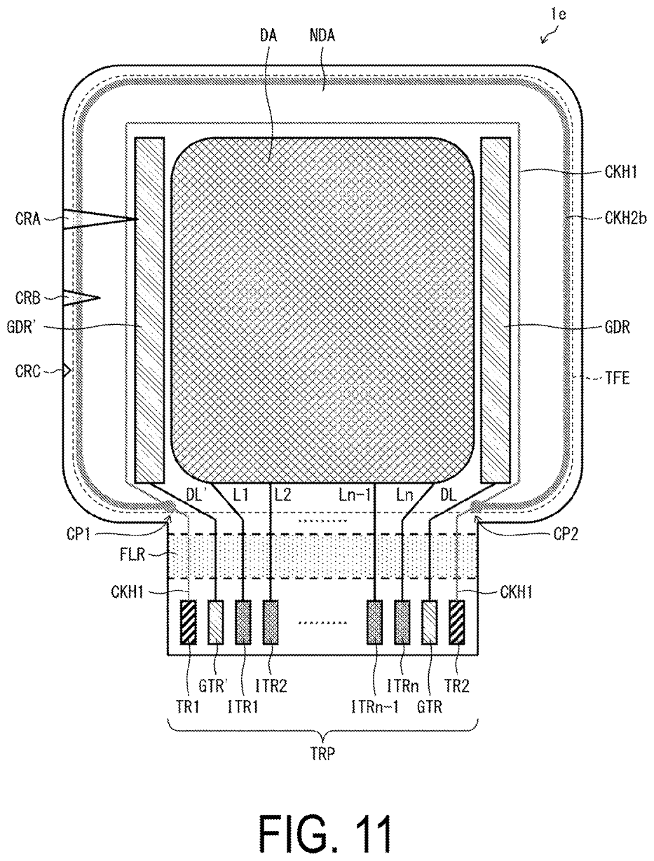

Next, a fourth embodiment of the disclosure will be described with reference to FIG. 11. A display device 1e of the present embodiment is different from that of the first to third embodiments in that the line width of a crack detection wiring line CKH2b is equal to or greater than two-times the line width of the crack detection wiring line CKH1 disposed closer to the display region DA than the crack detection wiring line CKH2b. The others are as described in the first to third embodiments. For convenience of description, members having the same functions as those of the members illustrated in the drawings in the first to third embodiments are denoted by the same reference numerals, and descriptions thereof will be omitted. FIG. 11 is a schematic plan view illustrating a configuration of the display device 1e according to the fourth embodiment.

As illustrated in FIG. 11, in the display device 1e, the line width of the crack detection wiring line CKH2b is equal to or greater than two-times the line width of the crack detection wiring line CKH1 disposed closer to the display region DA than the crack detection wiring line CKH2b.

In the present embodiment, the crack detection wiring line CKH1 and the crack detection wiring line CKH2b are formed of the same material. Thus, the specific resistance value of the crack detection wiring line CKH1 and the specific resistance value of the crack detection wiring line CKH2b are the same. Also, the wiring line length of the crack detection wiring line CKH1 and the wiring line length of the crack detection wiring line CKH2b are the same, and the film thickness of the crack detection wiring line CKH1 and the film thickness of the crack detection wiring line CKH2b are the same. By setting the line width of the crack detection wiring line CKH2b to two-times the line width of the crack detection wiring line CKH1, the resistance value R1 of the crack detection wiring line CKH1 is set to two-times the resistance value R2 of the crack detection wiring line CKH2b (R1=2×R2). However, no such limitation is intended.

As described above, in the example of the present embodiment described above, the plurality of crack detection wiring lines include two wiring lines, the crack detection wiring line CKH1 and the crack detection wiring line CKH2b, and the line width of the crack detection wiring line CKH2b is equal to or greater than two-times the line width of the crack detection wiring line CKH1. However, no such limitation is intended, and with two of the plurality of crack detection wiring lines, the line width of one of the crack detection wiring lines may be different from the line width of the other crack detection wiring line by two-times or greater. According to the display device 1e and the inspection method using the display device 1e, improved yield (non-defect rate) and reduced manufacturing costs can be achieved and non-illustrated localized crack inspection can also be performed.

Though not illustrated, by forming the crack detection wiring line CKH1 and the crack detection wiring line CKH2b of the same material, the specific resistance value of the crack detection wiring line CKH1 and the specific resistance value of the crack detection wiring line CKH2b may be made the same, the wiring line length of the crack detection wiring line CKH1 and the wiring line length of the crack detection wiring line CKH2b may be made the same, and the line width of the crack detection wiring line CKH1 and the line width of the crack detection wiring line CKH2b may be made the same, and then by making the film thickness of the crack detection wiring line CKH2b two-times the film thickness of the crack detection wiring line CKH1, the resistance value R1 of the crack detection wiring line CKH1 may be made two-times (R1=2×R2) the resistance value R2 of the crack detection wiring line CKH2b.

In the example described above, the plurality of crack detection wiring lines include two wiring lines, the crack detection wiring line CKH1 and the crack detection wiring line CKH2b, and the film thickness of the crack detection wiring line CKH2b is equal to or greater than two-times the film thickness of the crack detection wiring line CKH1. However, no such limitation is intended, and with two of the plurality of crack detection wiring lines, the film thickness of one of the crack detection wiring lines may be different from the film thickness of the other crack detection wiring line by two-times or greater.

According to the display device described above and the inspection method using the display device described above, improved yield (non-defect rate) and reduced manufacturing costs can be achieved and non-illustrated localized crack inspection can also be performed.

### Fifth Embodiment

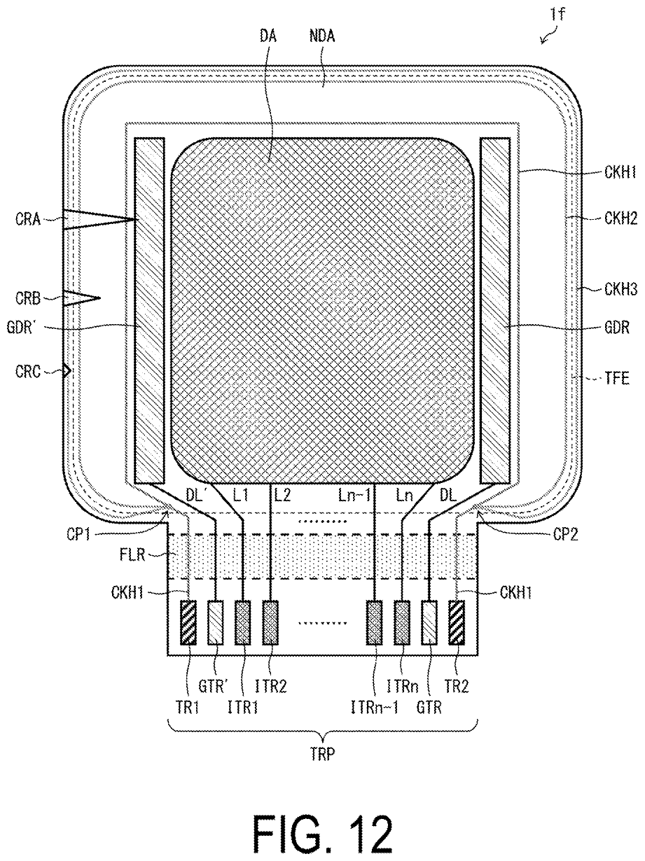

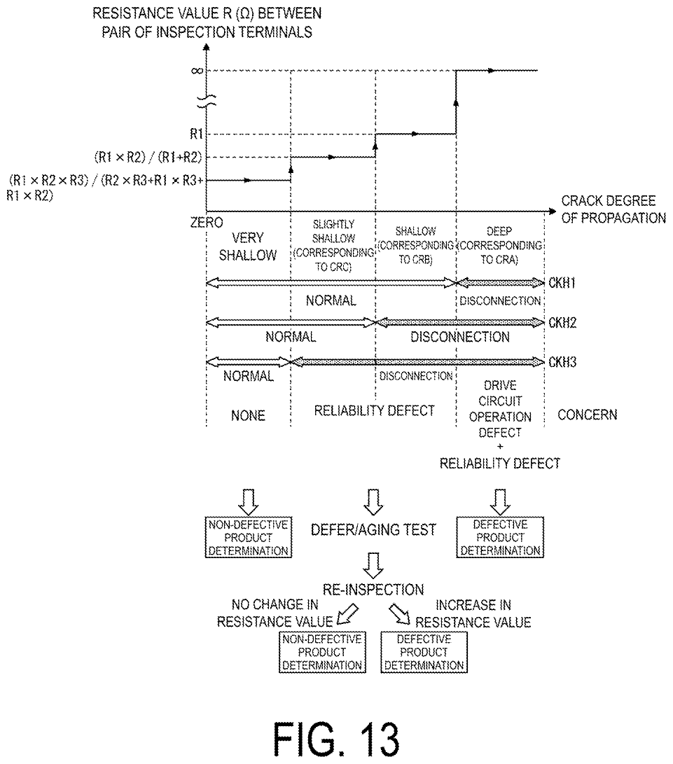

Next, a fifth embodiment of the disclosure will be described with reference to FIG. 12 and FIG. 13. The display device 1f of the present embodiment is different from that of the first to fourth embodiments in that the plurality of crack detection wiring lines include three wiring lines, namely the crack detection wiring line CKH1 disposed closest to the display region DA, a crack detection wiring line CKH3 disposed farthest from the display region DA, and the crack detection wiring line CKH2 disposed between the crack detection wiring line CKH1 and the crack detection wiring line CKH3. The others are as described in the first to fourth embodiments. For convenience of description, members having the same functions as those of the members illustrated in the drawings in the first to fourth embodiments are denoted by the same reference numerals, and descriptions thereof will be omitted.

FIG. 12 is a schematic plan view illustrating a configuration of the display device 1f according to the fifth embodiment.

The resistance value R1 of the crack detection wiring line CKH1 illustrated in FIG. 12 is obtained via the following Formula (5).

$$R 1 = ( ρ1 \times L 1 ) / ( W 1 \times d 1 ) \qquad Formula ( 5 )$$

In Formula (5), p1 is the specific resistance value of the crack detection wiring line CKH1, L1 is the wiring line length of the crack detection wiring line CKH1, W1 is the wiring line width of the crack detection wiring line CKH1, and d1 is the film thickness of the crack detection wiring line CKH1.

The resistance value R2 of the crack detection wiring line CKH2 illustrated in FIG. 12 is obtained via the following Formula (6).

$$R 2 = ( ρ2 \times L 2 ) / ( W 2 \times d 2 ) \qquad Formula ( 6 )$$

In Formula (6), p2 is the specific resistance value of the crack detection wiring line CKH2, L2 is the wiring line length of the crack detection wiring line CKH2, W2 is the line width of the crack detection wiring line CKH2, and d2 is the film thickness of the crack detection wiring line CKH2.

The resistance value R3 of the crack detection wiring line CKH3 illustrated in FIG. 12 is obtained via the following Formula (7).

$$R 3 = ( ρ3 \times L 3 ) / ( W 3 \times d 3 ) \qquad Formula ( 7 )$$

In Formula (7), p3 is the specific resistance value of the crack detection wiring line CKH3, L3 is the wiring line length of the crack detection wiring line CKH3, W3 is the line width of the crack detection wiring line CKH3, and d3 is the film thickness of the crack detection wiring line CKH3.

The resistance value R measured via the first terminal TR1 and the second terminal TR2 forming the pair of inspection terminals is obtained via the following Formula (8) and Formula (9) as a combined wiring line resistance value of the crack detection wiring lines CKH1, CKH2, and CKH3.

$$1 / R = ( 1 / R 1 ) + ( 1 / R 2 ) + ( 1 / R 3 ) \qquad Formula ( 8 )$$

$$R = ( R 1 \times R 2 \times R 3 ) / ( R 2 \times R 3 + R 1 \times R 3 + R 1 \times R 2 ) \qquad Formula ( 9 )$$

In the present embodiment, the resistance value R1 of the crack detection wiring line CKH1 is set to a value equal to or greater than two-times the resistance value R2 of the crack detection wiring line CKH2, and the resistance value R2 of the crack detection wiring line CKH2 is set to a value equal to or greater than two-times the resistance value R3 of the crack detection wiring line CKH3. Specifically, the resistance value R1 of the crack detection wiring line CKH1 is set to a value two-times the resistance value R2 of the crack detection wiring line CKH2 (R1=2×R2), the resistance value R2 of the crack detection wiring line CKH2 is set to a value two-times the resistance value R3 of the crack detection wiring line CKH3 (R2=2×R3), and the relationship between the resistance value R1 of the crack detection wiring line CKH1, the resistance value R2 of the crack detection wiring line CKH2, and the resistance value R3 of the crack detection wiring line CKH3 satisfies R2=(1/2)×R1 and R3=(1/2)×R2=(1/4)×R1.

As illustrated in FIG. 12, in the display device 1f, the sealing layer TFE is provided covering the display region DA and a portion of the frame region NDA continuing on from the display region DA, and a portion surrounding the display region DA of the crack detection wiring line CKH3 disposed farthest from the display region DA from among the crack detection wiring line CKH1, the crack detection wiring line CKH2, and the crack detection wiring line CKH3 is provided on the outer side of the end portion of the sealing layer TFE indicated by a broken line in the diagram. However, no such limitation is intended, and for example, at least a portion of the portion surrounding the display region DA of the crack detection wiring line CKH2 and the crack detection wiring line CKH3 may be provided on the outer side of the end portion of the sealing layer TFE indicated by a broken line in the diagram.

FIG. 13 is a diagram illustrating an example of an inspection method using the display device 1f.

By applying a voltage between the first terminal TR1 and the second terminal TR2 forming the pair of inspection terminals in a parallel connection with the crack detection wiring line CKH1, the crack detection wiring line CKH2, and the crack detection wiring line CKH3, the resistance value R between the first terminal TR1 and the second terminal TR2 can be measured. The resistance value R stepwisely changes depending on how the crack is formed and the propagation propensity, and thus how much the crack has propagated can be deduced.

Though not illustrated, in the display device 1f illustrated in FIG. 12, in the case of a crack such as the crack CRC forming that is too shallow to damage the sealing film TFE, is not significant enough to effect the reliability of the display device f, and does not give rise to reliability concerns, as illustrated in FIG. 13, the crack detection wiring line CKH1, the crack detection wiring line CKH2, and the crack detection wiring line CKH3 are not disconnected and the display device 1f functions normally. Thus, in such a case, the resistance value R measured via the first terminal TR1 and the second terminal TR2 forming the pair of inspection terminals corresponds to R=(R1×R2×R3)/(R2×R3+R1×R3+R1×R2). Here, R1 is the resistance value of the crack detection wiring line CKH1, R2 is the resistance value of the crack detection wiring line CKH2, and R3 is the resistance value of the crack detection wiring line CKH3. Thus, in the present embodiment, the relationship between the resistance value R1 of the crack detection wiring line CKH1, the resistance value R2 of the crack detection wiring line CKH2, and the resistance value R3 of the crack detection wiring line CKH3 satisfies R2=(1/2)×R1 and R3=(1/4)×R1. Thus, in a case where R=(R1×R2×R3)/(R2×R3+R1×R3+R1×R2)=(1/7)R1 is obtained to be the resistance value R, the degree of crack propagation of the display device 1f is very shallow, and a non-defective product determination can be made.

In addition, in a case where the slightly shallow crack CRC is formed very near the sealing film TFE but has not damaged the sealing film TFE in the display device 1f illustrated in FIG. 12, there is a reliability defect concern due to the possibility of the slightly shallow crack CRC propagating inward and becoming a crack that can damage the sealing film TFE. When a crack such as the crack CRC is formed, as illustrated in FIG. 13, the crack detection wiring line CKH1 and the crack detection wiring line CKH2 are normal, and the crack detection wiring line CKH3 is disconnected. Thus, in such a case, in a first crack detection process, the resistance value R measured via the first terminal TR1 and the second terminal TR2 forming the pair of inspection terminals corresponds to the combined wiring line resistance value (R1×R2)/(R1+R2) of the resistance value R1 of the normal crack detection wiring line CKH1 and the resistance value R2 of the normal crack detection wiring line CKH2. In the present embodiment, in a case where, since R2=(1/2)×R1, R=(1/3)×R1 is obtained to be the resistance value R, this case is handled in a similar manner to the case of the shallow crack CRB that can damage a portion of the sealing film TFE described below, and the non-defective product determination and the defective product determination of the display device 1f may be deferred, and the aging test of a predetermined amount of time may be performed using the display device 1f for which determination has been deferred. Thereafter, the re-inspection process (second crack detection process) is performed and non-defective product determination is performed. Alternatively, this case may be handled in a similar manner to the case of a very shallow crack described above, and a non-defective product determination may be made without performing the aging test and the re-inspection process (second crack detection process).

Further, in a case where the shallow crack CRB that can damage a portion of the sealing film TFE has formed in the display device 1f in FIG. 12, there are reliability defect concerns. When a crack such as the crack CRB is formed, as illustrated in FIG. 13, the crack detection wiring line CKH1 is normal, and the crack detection wiring line CKH2 and the crack detection wiring line CKH3 are disconnected. Thus, in such a case, in a first crack detection process, the resistance value R measured via the first terminal TR1 and the second terminal TR2 forming the pair of inspection terminals corresponds to the resistance value R1 of the normal crack detection wiring line CKH1. In a case where R=R1 is obtained to be the resistance value R, the non-defective product determination and the defective product determination of the display device 1f is deferred and the aging test of a predetermined amount of time is performed using the display device 1f for which determination has been deferred. Thereafter, in the re-inspection process (second crack detection process), the resistance value R is again measured via the first terminal TR1 and the second terminal TR2 forming the pair of inspection terminals. By comparing the resistance value R obtained in the first crack detection process with the resistance value R obtained in the re-inspection process (second crack detection process), it is possible to detect any change in the crack that occurs during the aging test of the predetermined amount of time. If there is no change between the resistance value R obtained in the first crack detection process and the resistance value R obtained in the re-inspection process (second crack detection process), the formed crack CRB is a crack without propagation propensity, and the display device 1f can be determined to be a non-defective product. On the other hand, if the resistance value R obtained in the re-inspection process (second crack detection process) is greater than the resistance value R obtained in the first crack detection process, the formed crack CRB is determined to be a crack with propagation propensity, and the display device 1f can be determined to be a defective product.

In addition, in a case where the deep crack CRA which can disconnect the control wiring line in the drive circuits GDR and GDR′ is formed in the display device 1f illustrated in FIG. 12, there is a drive circuit operation defect concern and a reliability defect concern due to the crack being able to damage the sealing film TFE. When a crack such as the crack CRA is formed, as illustrated in FIG. 13, the crack detection wiring line CKH1, the crack detection wiring line CKH2, and the crack detection wiring line CKH3 are all disconnected. Thus, in such a case, the resistance value R measured via the first terminal TR1 and the second terminal TR2 forming the pair of inspection terminals corresponds to ∞ (for example, 10 MΩ or greater). Thus, in a case where ∞ (for example, 10 MΩ or greater) is obtained to be the resistance value R, the degree of crack propagation of the display device 1f is deep, and thus a defective product determination can be made.

Since the relationship between the resistance value R1 of the crack detection wiring line CKH1, the resistance value R2 of the crack detection wiring line CKH2, and the resistance value R3 of the crack detection wiring line CKH3 provided in the display device 1f according to the present embodiment satisfies R2=(1/2)×R1 and R3=(1/2)×R2=(1/4)×R1, as described in the first embodiment on the basis of FIG. 5, a localized crack that can disconnect only the crack detection wiring line CKH1 and a localized crack that can disconnect only the crack detection wiring line CKH2 can be inspected.

In a case where a localized crack (not illustrated) that can disconnect only the crack detection wiring line CKH1 has formed in the display device 1f illustrated in FIG. 12, due to the disconnection of the crack detection wiring line CKH1, the resistance value R1 of the crack detection wiring line CKH1 is ∞ (for example, 10 MΩ or greater). Thus, the resistance value R measured via the first terminal TR1 and the second terminal TR2 forming the pair of inspection terminals corresponds to R=(R2×R3)/(R2+R3). In the present embodiment, in a case where, since R2=(1/2)×R1 and R3=(1/4)×R1, (1/6)R1 is obtained to be the resistance value R, it is considered that a localized crack that can disconnect only the crack detection wiring line CKH1 has been formed. Thus, the non-defective product determination and the defective product determination of the display device 1f are deferred, and the aging test of a predetermined amount of time may be performed using the display device 1f for which determination has been deferred. Thereafter, the re-inspection process (second crack detection process) is performed and non-defective product determination and defective product determination are performed. Alternatively, this case may be handled in a similar manner to the case of the deep crack CRA described above, and a defective product determination may be made without performing the aging test and the re-inspection process (second crack detection process).

Also, in a case where a localized crack (not illustrated) that can disconnect only the crack detection wiring line CKH2 has formed in the display device 1f illustrated in FIG. 12, due to the disconnection of the crack detection wiring line CKH2, the resistance value R2 of the crack detection wiring line CKH2 is ∞ (for example, 10 MΩ or greater). Thus, the resistance value R measured via the first terminal TR1 and the second terminal TR2 forming the pair of inspection terminals corresponds to R=(R1×R3)/(R1+R3). In the present embodiment, in a case where, since R3=(1/4)×R1, (1/5)R1 is obtained to be the resistance value R, it is considered that a localized crack that can disconnect only the crack detection wiring line CKH2 has been formed. Thus, the non-defective product determination and the defective product determination of the display device 1f are deferred, and the aging test of a predetermined amount of time may be performed using the display device 1f for which determination has been deferred. Thereafter, the re-inspection process (second crack detection process) is performed and non-defective product determination and defective product determination are performed. Alternatively, this case may be handled in a similar manner to the case of a very shallow crack described above, and a non-defective product determination may be made without performing the aging test and the re-inspection process (second crack detection process).

According to the display device 1f and the inspection method using the display device 1f, improved yield (non-defect rate) and reduced manufacturing costs can be achieved and non-illustrated localized crack inspection can also be performed.

### Sixth Embodiment

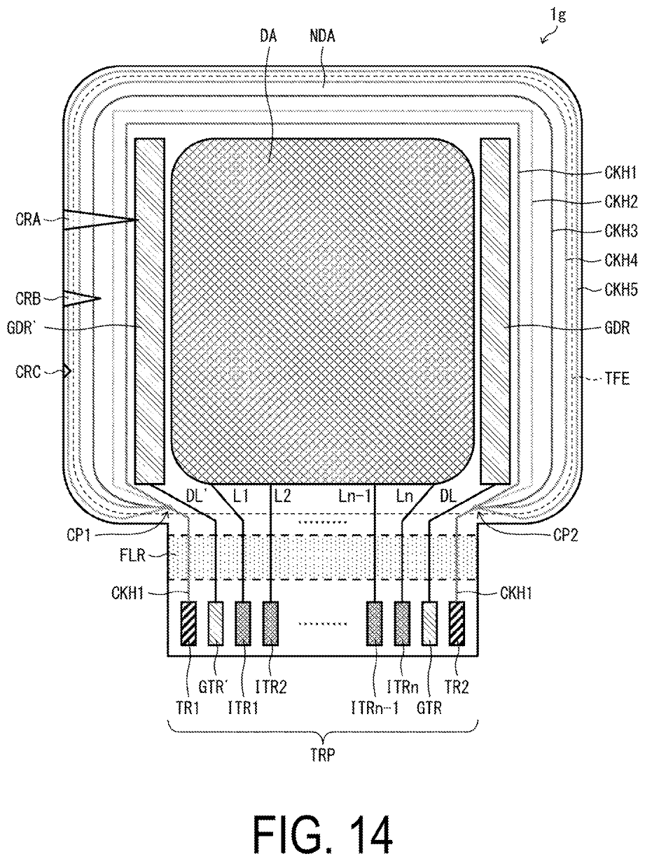

Next, a sixth embodiment of the disclosure will be described with reference to FIG. 14 to FIG. 17. A display device 1g of the present embodiment is different from that of the first to fifth embodiments in that the plurality of crack detection wiring lines include five wiring lines, namely the crack detection wiring line CKH1 disposed closest to the display region DA, a crack detection wiring line CKH5 disposed farthest from the display region DA, the crack detection wiring line CKH3 disposed between the crack detection wiring line CKH1 and the crack detection wiring line CKH5, the crack detection wiring line CKH2 disposed between the crack detection wiring line CKH1 and the crack detection wiring line CKH3, and the crack detection wiring line CKH4 disposed between the crack detection wiring line CKH3 and the crack detection wiring line CKH5. The others are as described in the first to fifth embodiments. For convenience of explanation, components having the same functions as those illustrated in diagrams of the first to fifth embodiments are appended with the same reference signs, and descriptions thereof may be omitted.

FIG. 14 is a schematic plan view illustrating a configuration of the display device 1g according to a sixth embodiment.

In the display device 1g illustrated in FIG. 14, the plurality of crack detection wiring lines include five wiring lines, namely the crack detection wiring line CKH1 disposed closest to the display region DA, the crack detection wiring line CKH5 disposed farthest from the display region DA, the crack detection wiring line CKH3 disposed between the crack detection wiring line CKH1 and the crack detection wiring line CKH5, the crack detection wiring line CKH2 disposed between the crack detection wiring line CKH1 and the crack detection wiring line CKH3, and the crack detection wiring line CKH4 disposed between the crack detection wiring line CKH3 and the crack detection wiring line CKH5.

In the display device 1g illustrated in FIG. 14, all of the adjacent pairs of the plurality of crack detection wiring lines CKH1 to CKH5 (the crack detection wiring line CKH1 and the crack detection wiring line CKH2, the crack detection wiring line CKH2 and the crack detection wiring line CKH3, the crack detection wiring line CKH3 and the crack detection wiring line CKH4, and the crack detection wiring line CKH4 and the crack detection wiring line CKH5) are formed of an inner crack detection wiring line closer to the display region DA and an outer crack detection wiring line farther from the display region DA. For example, in the case of the adjacent pair of the crack detection wiring line CKH1 and the crack detection wiring line CKH2, the crack detection wiring line CKH1 is the inner crack detection wiring line closer to the display region DA and the crack detection wiring line CKH2 is the outer crack detection wiring line farther from the display region DA. The outer crack detection wiring line is provided around the periphery from the first end (end on the left side at the contact point CP1 in the diagram) of the inner crack detection wiring line to the second end (end on the right side at the contact point CP2 in the diagram).

In the display device 1g illustrated in FIG. 14, the resistance value R measured via the first terminal TR1 and the second terminal TR2 forming the pair of inspection terminals corresponds to R=(R1×R2×R3×R4×R5)/(R2×R3×R4×R5+R1×R3×R4×R5+R1×R2×R4×R5+R1×R2×R3×R5+R1×R2×R3×R4). Here, R1 is the resistance value of the crack detection wiring line CKH1, R2 is the resistance value of the crack detection wiring line CKH2, R3 is the resistance value of the crack detection wiring line CKH3, R4 is the resistance value of the crack detection wiring line CKH4, and R5 is the resistance value of the crack detection wiring line CKH5.

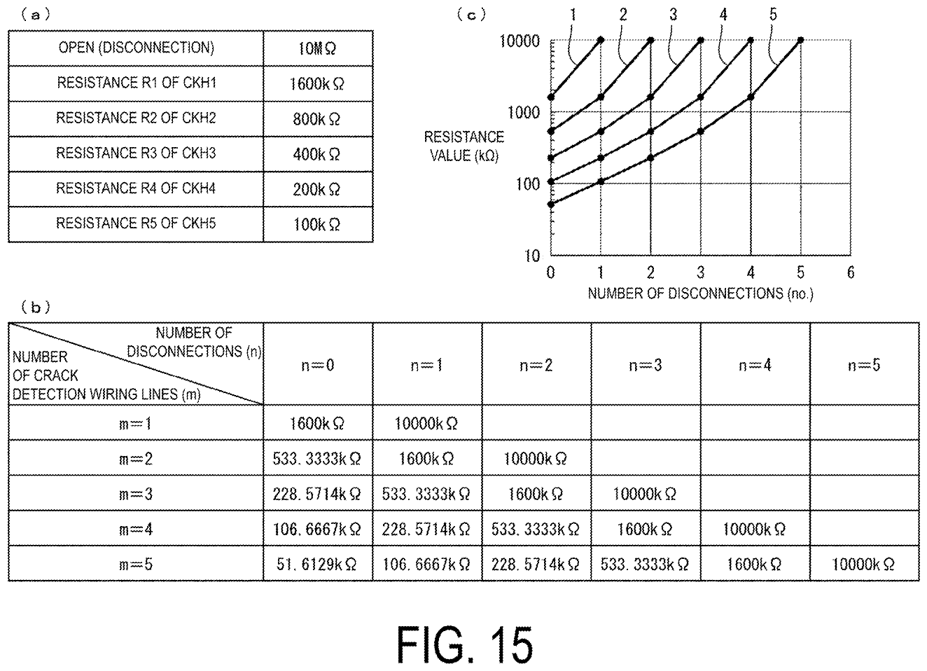

(a) of FIG. 15 is a diagram showing the resistance values of the crack detection wiring lines CKH1 to CKH5 forming the plurality of crack detection wiring lines CKH1 to CKH5 as a first example of the display device 1g of the sixth embodiment. (b) and (c) of FIG. 15 are diagrams showing the change in the resistance value R measured via the first terminal TR1 and the second terminal TR2 according to the number of disconnections in the case of the crack detection wiring lines CKH1 to CKH5 forming the first to fifth lines as the first example of the display device 1g of the sixth embodiment.

As shown in (a) of FIG. 15, in the first example of the display device 1g according to the present embodiment, the relationship between the resistance value R1 of the crack detection wiring line CKH1, the resistance value R2 of the crack detection wiring line CKH2, the resistance value R3 of the crack detection wiring line CKH3, the resistance value R4 of the crack detection wiring line CKH4, and the resistance value R5 of the crack detection wiring line CKH5 satisfies R2=(1/2)×R1, R3=(1/2)×R2=(1/4)×R1, R4=(1/2)×R3=(1/4)×R2=(1/8)× R1, and R5=(1/2)×R4=(1/4)×R3=(1/8)×R2=(1/16)×R1. In addition, the resistance value R in a case where all are disconnected (in the case of open) is normally ∞, but for convenience of illustration (because it cannot be illustrated), in the diagrams, the resistance value in the case of open is assumed to be 10 MΩ.

As described above, in the first example of the display device 1g, the resistance values of any two adjacent crack detection wiring lines selected from the plurality of crack detection wiring lines CKH1 to CKH5 are set so that the resistance value of the crack detection wiring line disposed closer to the display region DA is equal to or greater than two-times the resistance value of the crack detection wiring line disposed farther from the display region DA.

In the first example of the display device 1g, as shown in (b) and (c) of FIG. 15, the resistance values R measured via the first terminal TR1 and the second terminal TR2 are different depending on the number of disconnections n of the plurality of crack detection wiring lines CKH1 to CKH5 in the portion provided around the periphery of the display region DA.

The resistance values depending on the number of disconnections n shown in (b) and (c) of FIG. 15 are, in all cases, the result of sequential disconnections in the direction from the crack detection wiring line farthest from the display region DA toward the display region DA.

According to the first example of the display device 1g, as shown in (b) and (c) of FIG. 15, in any cases where a number m of crack detection wiring lines forming the plurality of crack detection wiring lines is from 2 to 5, the resistance value R measured via the first terminal TR1 and the second terminal TR2 changes relatively greatly depending on the number of disconnections n. This makes it easier to detect cracks.

According to the first example of the display device 1g and the inspection method using the first example of the display device 1g, improved yield (non-defect rate) and reduced manufacturing costs can be achieved and non-illustrated localized crack inspection can also be performed.

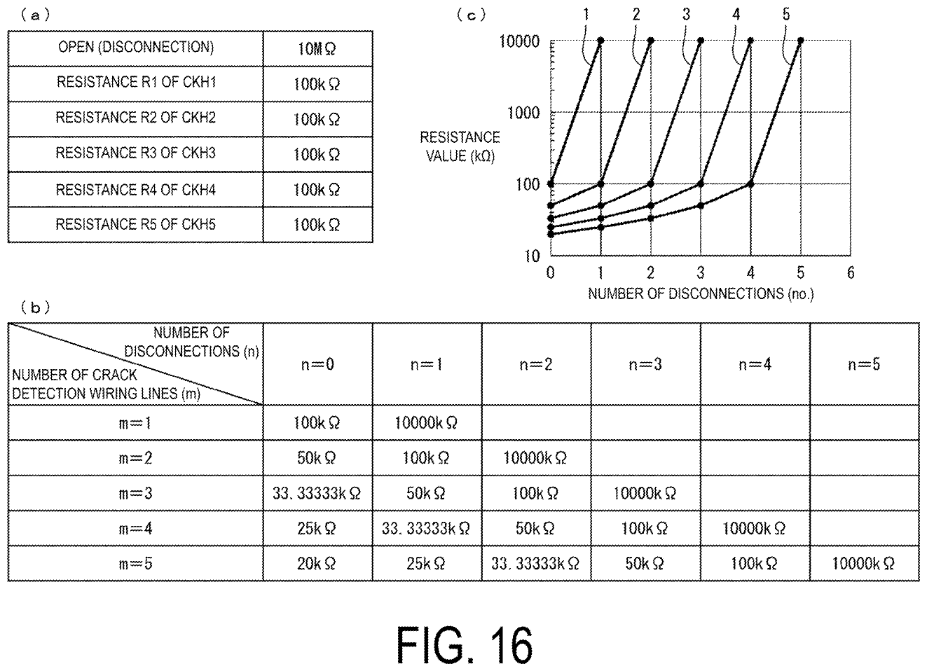

(a) of FIG. 16 is a diagram showing the resistance values of the crack detection wiring lines CKH1 to CKH5 forming the plurality of crack detection wiring lines CKH1 to CKH5 as a second example of the display device 1g of the sixth embodiment. (b) and (c) of FIG. 16 are diagrams showing the change in the resistance value R measured via the first terminal TR1 and the second terminal TR2 according to the number of disconnections in the case of the crack detection wiring lines CKH1 to CKH5 forming the first to fifth lines as the second example of the display device 1g of the sixth embodiment.

As shown in (a) of FIG. 16, in the second example of the display device 1g according to the present embodiment, the relationship between the resistance value R1 of the crack detection wiring line CKH1, the resistance value R2 of the crack detection wiring line CKH2, the resistance value R3 of the crack detection wiring line CKH3, the resistance value R4 of the crack detection wiring line CKH4, and the resistance value R5 of the crack detection wiring line CKH5 satisfies R1=R2=R3=R4=R5. In addition, the resistance value R in a case where all are disconnected (in the case of open) is normally ∞, but for convenience of illustration (because it cannot be illustrated), in the diagrams, the resistance value in the case of open is assumed to be 10 MΩ.

As described above, in the second example of the display device 1g, the resistance values R1 to R5 of the crack detection wiring lines CKH1 to CKH5 forming the plurality of crack detection wiring lines CKH1 to CKH5 are all the same.

In the second example of the display device 1g, as shown in (b) and (c) of FIG. 16, the resistance values R measured via the first terminal TR1 and the second terminal TR2 are different depending on the number of disconnections n of the plurality of crack detection wiring lines CKH1 to CKH5 in the portion provided around the periphery of the display region DA.

The resistance values depending on the number of disconnections n shown in (b) and (c) of FIG. 16 are, in all cases, the result of sequential disconnections in the direction from the crack detection wiring line farthest from the display region DA toward the display region DA.

According to the second example of the display device 1g, as shown in (b) and (c) of FIG. 16, in any cases where a number m of crack detection wiring lines forming the plurality of crack detection wiring lines is from 2 to 5, the resistance value R measured via the first terminal TR1 and the second terminal TR2 changes depending on the number of disconnections n. Thus, crack detection can be performed.

As described above, according to the second example of the display device 1g and the inspection method using the second example of the display device 1g, improved yield (non-defect rate) and reduced manufacturing costs can be achieved.

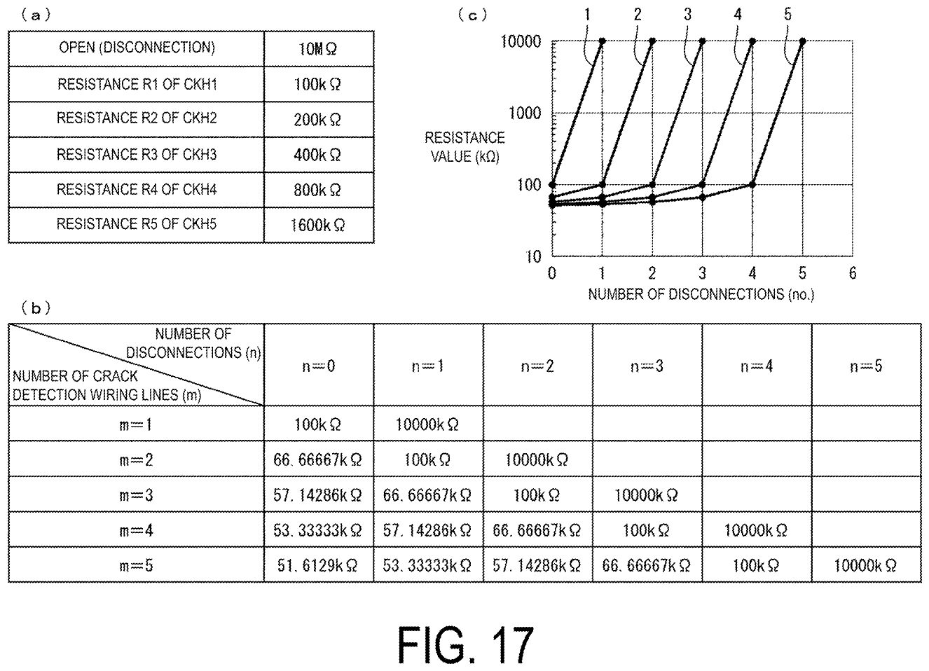

(a) of FIG. 17 is a diagram showing the resistance values of the crack detection wiring lines CKH1 to CKH5 forming the plurality of crack detection wiring lines CKH1 to CKH5 as a third example of the display device 1g of the sixth embodiment. (b) and (c) of FIG. 17 are diagrams showing the change in the resistance value R measured via the first terminal TR1 and the second terminal TR2 according to the number of disconnections in the case of the crack detection wiring lines CKH1 to CKH5 forming the first to fifth lines as the third example of the display device 1g of the sixth embodiment.

As shown in (a) of FIG. 17, in the third example of the display device 1g according to the present embodiment, the relationship between the resistance value R1 of the crack detection wiring line CKH1, the resistance value R2 of the crack detection wiring line CKH2, the resistance value R3 of the crack detection wiring line CKH3, the resistance value R4 of the crack detection wiring line CKH4, and the resistance value R5 of the crack detection wiring line CKH5 satisfies R2=2×R1, R3=2×R2=4×R1, R4=2×R3=4×R2=8×R1, and R5=2×R4=4×R3=8×R2=16×R1. In addition, the resistance value R in a case where all are disconnected (in the case of open) is normally ∞, but for convenience of illustration (because it cannot be illustrated), in the diagrams, the resistance value in the case of open is assumed to be 10 MΩ.

As described above, in the third example of the display device 1g, the resistance values of any two adjacent crack detection wiring lines selected from the plurality of crack detection wiring lines CKH1 to CKH5 are set so that the resistance value of the crack detection wiring line disposed farther from the display region DA is equal to or greater than two-times the resistance value of the crack detection wiring line disposed closer to the display region DA.

In the third example of the display device 1g, as shown in (b) and (c) of FIG. 17, the resistance values R measured via the first terminal TR1 and the second terminal TR2 are different depending on the number of disconnections n of the plurality of crack detection wiring lines CKH1 to CKH5 in the portion provided around the periphery of the display region DA.

The resistance values depending on the number of disconnections n shown in (b) and (c) of FIG. 17 are, in all cases, the result of sequential disconnections in the direction from the crack detection wiring line farthest from the display region DA toward the display region DA.

According to the third example of the display device 1g, as shown in (b) and (c) of FIG. 17, in any cases where a number m of crack detection wiring lines forming the plurality of crack detection wiring lines is from 2 to 5, the resistance value R measured via the first terminal TR1 and the second terminal TR2 changes depending on the number of disconnections n. Thus, crack detection can be performed.

According to the third example of the display device 1g and the inspection method using the third example of the display device 1g, improved yield (non-defect rate) and reduced manufacturing costs can be achieved and non-illustrated localized crack inspection can also be performed.

Three cases have been described above regarding the relationship between the resistance values in the crack detection wiring lines CKH1 to CKH5 in the display device 1g of the sixth embodiment, namely the first example in which the crack detection wiring line disposed inward closer to the display region DA has a higher resistance value, the second example in which all of the resistance values are the same, and the third example in which the crack detection wiring line disposed outward farther from the display region DA has a higher resistance value. Of these, the first example, in which the crack detection wiring line disposed inward closer to the display region DA has a higher resistance value, is the most preferable from the perspective of resistance value design due to the amount of change in the resistance values when the number of disconnections increases being greater and easy to discern.

### Seventh Embodiment

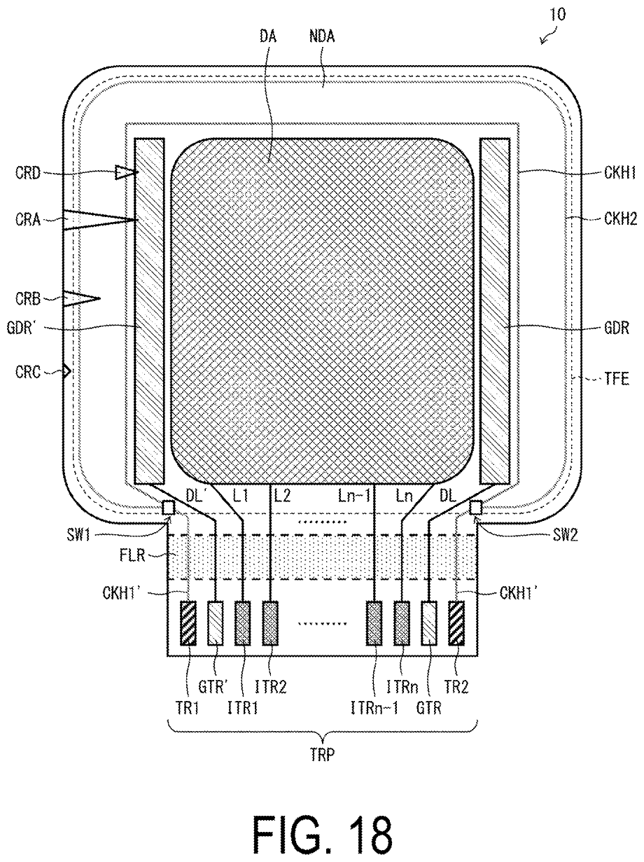

Next, with reference to FIG. 18, a seventh embodiment of the disclosure will be described. A display device 10 according to the present embodiment is different from that in the first to sixth embodiments in that the electrical connection between the first end of one selected from the crack detection wiring line CKH1 and the crack detection wiring line CKH2 and the first terminal TR1 and the electrical connection between the second end and the second terminal TR2 are performed in a first period, and the electrical connection between the first end of the other one selected from the crack detection wiring line CKH1 and the crack detection wiring line CKH2 and the first terminal TR1 and the electrical connection between the second end and the second terminal TR2 are performed in a second period different from the first period. The others are as described in the first to sixth embodiments. For convenience of explanation, components having the same functions as those illustrated in diagrams of the first to sixth embodiments are appended with the same reference signs, and descriptions thereof may be omitted.

FIG. 18 is a schematic plan view illustrating a configuration of the display device 10 according to a seventh embodiment.

As illustrated in FIG. 18, in the display device 10, the electrical connection between the first end of the crack detection wiring line CKH1, one selected from the crack detection wiring line CKH1 and the crack detection wiring line CKH2, and the first terminal TR1 and the electrical connection between the second end of the crack detection wiring line CKH1 and the second terminal TR2 are performed in the first period, and the electrical connection between the first end of the crack detection wiring line CKH2, the other one selected from the crack detection wiring line CKH1 and the crack detection wiring line CKH2, and the first terminal TR1 and the electrical connection between the second end of the crack detection wiring line CKH2 and the second terminal TR2 are performed in the second period different from the first period.

As illustrated in FIG. 18, the display device 10 further includes a first switching circuit SW1 provided between the first end of the crack detection wiring line CKH1 and the crack detection wiring line CKH2 and a wiring line CKH1′ extending from the first terminal TR1 and a second switching circuit SW2 provided between the second end of the crack detection wiring line CKH1 and the crack detection wiring line CKH2 and the wiring line CKH1′ extending from the second terminal TR2.

The first switching circuit SW1 and the second switching circuit SW2 perform the electrical connection between the first end of the crack detection wiring line CKH1, one selected from the crack detection wiring line CKH1 and the crack detection wiring line CKH2, and the first terminal TR1 and the electrical connection between the second end of the crack detection wiring line CKH1 and the second terminal TR2 in the first period and perform the electrical connection between the first end of the crack detection wiring line CKH2, the other one selected from the crack detection wiring line CKH1 and the crack detection wiring line CKH2, and the first terminal TR1 and the electrical connection between the second end of the crack detection wiring line CKH2 and the second terminal TR2 in the second period different from the first period.

With the first switching circuit SW1 and the second switching circuit SW2, the connection switching in the first period and the second period described above may be performed automatically at a predetermined interval using a predetermined signal or may be performed by user selection. The configuration of a known switching circuit can be used for the first switching circuit SW1 and the second switching circuit SW2 that perform switching of the connection described above.

With the display device 10, in a case where the resistance value R1 of the crack detection wiring line CKH1 is greater than the resistance value R2 of the crack detection wiring line CKH2, in a case where the resistance value R1 of the crack detection wiring line CKH1 is less than the resistance value R2 of the crack detection wiring line CKH2, and in a case where the resistance value R1 of the crack detection wiring line CKH1 and the resistance value R2 of the crack detection wiring line CKH2 are the same, an inspection can be performed in a similar manner as in the inspection method according to the first embodiment described above on the basis of FIGS. 3 and 5.

According to the display device 10 and the inspection method using the display device 10, in a crack detection process (for example, the first crack detection process), the electrical connection between the first end of each crack detection wiring line sequentially selected from the crack detection wiring line CKH1 and the crack detection wiring line CKH2 of the plurality of crack detection wiring lines and the first terminal TR1 and the electrical connection between the second end and the second terminal TR2 are performed in different period, and the degree of crack propagation of the display device 10 can be determined on the basis of the plurality of resistance values measured in the different periods via the first terminal TR1 and the second terminal TR2. Thus, according to the display device 10 and the inspection method using the display device 10, improved yield (non-defect rate) and reduced manufacturing costs can be achieved and inspection of the localized crack CRD can also be performed.

### Supplement

### First Aspect

A display device includes:
a display region;
a frame region around a periphery of the display region;
a terminal portion including
a first terminal and a second terminal forming a pair of inspection terminals, and
a plurality of input terminals provided between the first terminal and the second terminal and connected respectively to a plurality of first signal lines extending from the display region and in a signal line formation region of the frame region; and
a plurality of crack detection wiring lines provided in the frame region, the plurality of crack detection wiring lines each including a first end and a second end disposed on either side of the signal line formation region,
wherein each first end of the plurality of crack detection wiring lines is electrically connected to the first terminal, the first terminal being closer to the first end than the second terminal, and
each second end of the plurality of crack detection wiring lines is electrically connected to the second terminal, the second terminal being closer to the second end than the first terminal.

### Second Aspect

In the display device according to the first aspect,
of two of the plurality of crack detection wiring lines, one of the two crack detection wiring lines is provided surrounding a periphery of the other of the two crack detection wiring lines.

### Third Aspect

In the display device according to the first or second aspect,
all two adjacent crack detection wiring lines of the plurality of crack detection wiring lines are formed of an inner crack detection wiring line closer to the display region and an outer crack detection wiring line farther from the display region, and
the outer crack detection wiring line is provided surrounding a periphery of the inner crack detection wiring line.

### Fourth Aspect

In the display device according to any one of the first to third aspects,
the first end of one of the plurality of crack detection wiring lines extends to the first terminal and is connected to the first terminal, the first end of the plurality of crack detection wiring lines other than the one of the plurality of crack detection wiring lines connected to the first terminal is electrically connected to the first terminal via the one of the plurality of crack detection wiring lines connected to the first terminal,
the second end of one of the plurality of crack detection wiring lines extends to the second terminal and is connected to the second terminal, and the second end of the plurality of crack detection wiring lines other than the one of the plurality of crack detection wiring lines connected to the second terminal is electrically connected to the second terminal via the one of the plurality of crack detection wiring lines connected to the second terminal.

### Fifth Aspect

In the display device according to any one of the first to fourth aspects,
a resistance value measured via the first terminal and the second terminal is different depending on a number of disconnections of the plurality of crack detection wiring lines in a portion provided around the periphery of the display region.

### Sixth Aspect

In the display device according to any one of the first to fifth aspects,
each resistance value of each crack detection wiring line forming the plurality of crack detection wiring lines is different.

### Seventh Aspect

In the display device according to any one of the first to fifth aspects,
each resistance value of each crack detection wiring line forming the plurality of crack detection wiring lines is identical.

### Eighth Aspect

In the display device according to the sixth aspect,
each resistance value is higher for crack detection wiring lines disposed closer to the display region.

### Ninth Aspect

In the display device according to the eighth aspect,
resistance values of any two adjacent crack detection wiring lines selected from the plurality of crack detection wiring lines are set in a manner that the resistance value of the crack detection wiring line disposed closer to the display region is equal to or greater than two-times the resistance value of the crack detection wiring line disposed farther from the display region.

### Tenth Aspect

In the display device according to any one of the first to ninth aspect,
of two of the plurality of crack detection wiring lines, a length of one of the two crack detection wiring lines is different from a length of the other of the two crack detection wiring lines by two-times or greater.

### Eleventh Aspect

In the display device according to the tenth aspect,
the one of the two crack detection wiring lines is disposed closer to the display region than the other of the two crack detection wiring lines, and
the length of the one of the two crack detection wiring lines is equal to or greater than two-times the length of the other of the two crack detection wiring lines.

### Twelfth Aspect

In the display device according to any one of the first to eleventh aspects,
of two of the plurality of crack detection wiring lines, a line width of one of the two crack detection wiring lines is different from a line width of the other of the two crack detection wiring lines by two-times or greater.

### Thirteenth Aspect

In the display device according to the twelfth aspect,
the one of the two crack detection wiring lines is disposed closer to the display region than the other of the two crack detection wiring lines, and
the line width of the other of the two crack detection wiring lines is equal to or greater than two-times the line width of the one of the two crack detection wiring lines.

### Fourteenth Aspect

In the display device according to any one of the first to thirteenth aspect,
of two of the plurality of crack detection wiring lines, a film thickness of one of the two crack detection wiring lines is different from a film thickness of the other of the two crack detection wiring lines by two-times or greater.

### Fifteenth Aspect

In the display device according to the fourteenth aspect,
the one of the two crack detection wiring lines is disposed closer to the display region than the other of the two crack detection wiring lines, and
the film thickness of the other of the two crack detection wiring lines is equal to or greater than two-times the film thickness of the one of the two crack detection wiring lines.

### Sixteenth Aspect

In the display device according to any one of the first to fifteenth aspect,
of two of the plurality of crack detection wiring lines, a specific resistance value of one of the two crack detection wiring lines is different from a specific resistance value of the other of the two crack detection wiring lines by two-times or greater.

### Seventeenth Aspect

In the display device according to the sixteenth aspect,
the one of the two crack detection wiring lines is disposed closer to the display region than the other of the two crack detection wiring lines, and
the specific resistance value of the one of the two crack detection wiring lines is equal to or greater than two-times the specific resistance value of the other of the two crack detection wiring lines.

### Eighteenth Aspect

In the display device according to any one of the first to seventeenth aspect,
at least two of the plurality of crack detection wiring lines are formed of different materials.

### Nineteenth Aspect

In the display device according to the eighteenth aspect,
the plurality of crack detection wiring lines include a first crack detection wiring line and a second crack detection wiring line,
the first crack detection wiring line is provided closer to the display region than the second crack detection wiring line,
the first crack detection wiring line is formed of one or more selected from molybdenum and tungsten, and
the second crack detection wiring line is formed of one or more selected from aluminum, silver, and copper.

### Twentieth Aspect

In the display device according to any one of the first to fifth aspect,
resistance values of two of the plurality of crack detection wiring lines are set in a manner that the resistance value of the crack detection wiring line disposed closer to the display region is 1.68 times greater than the resistance value of the crack detection wiring line disposed farther from the display region.

### Twenty-First Aspect

In the display device according to the twentieth aspect,
a length of the crack detection wiring line disposed closer to the display region is 1.68 times greater than a length of the crack detection wiring line disposed farther from the display region.

### Twenty-Second Aspect

The display device according to any one of the first to twenty-first aspects further includes:
a sealing layer covering the display region and a portion of the frame region continuing on from the display region,
wherein at least a portion of a portion surrounding the display region of some crack detection wiring lines including a crack detection wiring line disposed farthest from the display region from among the plurality of crack detection wiring lines is provided on an outer side of an end portion of the sealing layer.

### Twenty-Third Aspect

The display device according to any one of the first to twenty-first aspects further includes:
a sealing layer covering the display region and a portion of the frame region continuing on from the display region,
wherein a portion of the plurality of crack detection wiring lines surrounding the display region is covered by the sealing layer.

### Twenty-Fourth Aspect

The display device according to any one of the first to twenty-third aspects further includes:
a drive circuit provided between a crack detection wiring line of the plurality of crack detection wiring lines disposed closest to the display region and the display region,
a drive signal input terminal provided between the first terminal and the second terminal of the terminal portion, and
a second signal line configured to electrically connect the drive circuit and the drive signal input terminal and provided in the signal line formation region of the frame region.

### Twenty-Fifth Aspect

In the display device according to any one of the first to twenty-fourth aspects,
at least two of the plurality of crack detection wiring lines are formed directly on different layers.

### Twenty-Sixth Aspect

A display device includes:
a display region;
a frame region around a periphery of the display region;
a terminal portion including
a first terminal and a second terminal forming a pair of inspection terminals, and
a plurality of input terminals provided between the first terminal and the second terminal and connected respectively to a plurality of first signal lines extending from the display region and in a signal line formation region of the frame region; and
a plurality of crack detection wiring lines provided in the frame region, the plurality of crack detection wiring lines each including a first end and a second end disposed on either side of the signal line formation region,
wherein an electrical connection between the first end of one crack detection wiring line selected from the plurality of crack detection wiring lines and the first terminal and an electrical connection between the second end and the second terminal are performed in a first period, and
an electrical connection between the first end of a different crack detection wiring line selected from the plurality of crack detection wiring lines and the first terminal and an electrical connection between the second end and the second terminal are performed in a second period different from the first period.

### Twenty-Seventh Aspect

The display device according to the twenty-sixth aspect further includes:
a first switching circuit provided between the first end of each one of the plurality of crack detection wiring lines and a wiring line extending from the first terminal, and
a second switching circuit provided between the second end of each one of the plurality of crack detection wiring lines and a wiring line extending from the second terminal,
wherein the first switching circuit and the second switching circuit
perform an electrical connection between the first end of the one crack detection wiring line and the first terminal and an electrical connection between the second end of the one crack detection wiring line and the second terminal in the first period, and
perform an electrical connection between the first end of the different crack detection wiring line and the first terminal and an electrical connection between the second end of the different crack detection wiring line and the second terminal in the second period.

### Twenty-Eighth Aspect

An inspection method using a display device includes:
performing a first crack detection using a display device including a display region, a frame region around a periphery of the display region, a terminal portion including a first terminal and a second terminal forming a pair of inspection terminals, and a plurality of input terminals provided between the first terminal and the second terminal and connected respectively to a plurality of first signal lines extending from the display region and in a signal line formation region of the frame region, and a plurality of crack detection wiring lines provided in the frame region, the plurality of crack detection wiring lines each including a first end and a second end disposed on either side of the signal line formation region,
wherein, in the first crack detection,
a degree of crack propagation of the display device is determined on a basis of resistance values of the plurality of crack detection wiring lines measured via the first terminal and the second terminal.

### Twenty-Ninth Aspect

In the inspection method using a display device according to the twenty-eighth aspect,
in the first crack detection,
the first end of each one of the plurality of crack detection wiring lines is electrically connected to the first terminal,
the second end of each one of the plurality of crack detection wiring lines is electrically connected to the second terminal, and
a degree of crack propagation of the display device is determined on a basis of a resistance value measured via the first terminal and the second terminal.

### Thirtieth Aspect

In the inspection method using a display device according to the twenty-eighth aspect,
in the first crack detection,
an electrical connection between the first end of each crack detection wiring line sequentially selected from the plurality of crack detection wiring lines and the first terminal and an electrical connection between the second end and the second terminal are performed in different periods, and
a degree of crack propagation of the display device is determined on a basis of a plurality of resistance values measured in the different periods via the first terminal and the second terminal.

### Thirty-First Aspect

The inspection method using a display device according to any one of the twenty-eighth to thirtieth aspects further includes:
performing a second crack detection after a predetermined amount of time elapses since completion of the first crack detection,
wherein the first crack detection and the second crack detection are an identical process.

### Thirty-Second Aspect

In the inspection method using a display device according to the thirty-first aspect,
a change in a crack is detected over the predetermined amount of time by comparing a degree of crack propagation determined in the first crack detection and a degree of crack propagation determined in the second crack detection.

### Appendix

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### INDUSTRIAL APPLICABILITY

The disclosure can be utilized for a display device and an inspection method using the display device.

1. A display device comprising:
a display region;
a frame region around a periphery of the display region;
a terminal portion including
a first terminal and a second terminal forming a pair of inspection terminals, and
a plurality of input terminals provided between the first terminal and the second terminal and connected respectively to a plurality of first signal lines extending from the display region and in a signal line formation region of the frame region; and
a plurality of crack detection wiring lines provided in the frame region, the plurality of crack detection wiring lines each including a first end and a second end disposed on either side of the signal line formation region,
wherein each first end of the plurality of crack detection wiring lines is electrically connected to the first terminal, the first terminal being closer to the first end than the second terminal, and
each second end of the plurality of crack detection wiring lines is electrically connected to the second terminal, the second terminal being closer to the second end than the first terminal.

2. (canceled)

3. The display device according to claim 1,
wherein all two adjacent crack detection wiring lines of the plurality of crack detection wiring lines are formed of an inner crack detection wiring line closer to the display region and an outer crack detection wiring line farther from the display region, and
the outer crack detection wiring line is provided surrounding a periphery of the inner crack detection wiring line.

4. The display device according to claim 1,
wherein the first end of one of the plurality of crack detection wiring lines extends to the first terminal and is connected to the first terminal,
the first end of the plurality of crack detection wiring lines other than the one of the plurality of crack detection wiring lines connected to the first terminal is electrically connected to the first terminal via the one of the plurality of crack detection wiring lines connected to the first terminal,
the second end of one of the plurality of crack detection wiring lines extends to the second terminal and is connected to the second terminal, and
the second end of the plurality of crack detection wiring lines other than the one of the plurality of crack detection wiring lines connected to the second terminal is electrically connected to the second terminal via the one of the plurality of crack detection wiring lines connected to the second terminal.

5. The display device according to claim 1,
wherein a resistance value measured via the first terminal and the second terminal is different depending on a number of disconnections of the plurality of crack detection wiring lines in a portion provided around the periphery of the display region.

6. The display device according to claim 1,
wherein each resistance value of each crack detection wiring line forming the plurality of crack detection wiring lines is different.

7. The display device according to claim 1,
wherein each resistance value of each crack detection wiring line forming the plurality of crack detection wiring lines is identical.

8. The display device according to claim 6,
wherein each resistance value is higher for crack detection wiring lines disposed closer to the display region.

9. The display device according to claim 8,
wherein resistance values of any two adjacent crack detection wiring lines selected from the plurality of crack detection wiring lines are set in a manner that the resistance value of the crack detection wiring line disposed closer to the display region is equal to or greater than two-times the resistance value of the crack detection wiring line disposed farther from the display region.

10. (canceled)

11. (canceled)

12. The display device according to claim 1,
wherein of two of the plurality of crack detection wiring lines, a line width of one of the two crack detection wiring lines is different from a line width of the other of the two crack detection wiring lines by two-times or greater.

13. The display device according to claim 12,
wherein the one of the two crack detection wiring lines is disposed closer to the display region than the other of the two crack detection wiring lines, and
the line width of the other of the two crack detection wiring lines is equal to or greater than two-times the line width of the one of the two crack detection wiring lines.

14. The display device according to claim 1,
wherein of two of the plurality of crack detection wiring lines, a film thickness of one of the two crack detection wiring lines is different from a film thickness of the other of the two crack detection wiring lines by two-times or greater.

15. The display device according to claim 14,
wherein the one of the two crack detection wiring lines is disposed closer to the display region than the other of the two crack detection wiring lines, and
the film thickness of the other of the two crack detection wiring lines is equal to or greater than two-times the film thickness of the one of the two crack detection wiring lines.

16. The display device according to claim 1,
wherein of two of the plurality of crack detection wiring lines, a specific resistance value of one of the two crack detection wiring lines is different from a specific resistance value of the other of the two crack detection wiring lines by two-times or greater.

17. The display device according to claim 16,
wherein the one of the two crack detection wiring lines is disposed closer to the display region than the other of the two crack detection wiring lines, and
the specific resistance value of the one of the two crack detection wiring lines is equal to or greater than two-times the specific resistance value of the other of the two crack detection wiring lines.

18. The display device according to claim 1,
wherein at least two of the plurality of crack detection wiring lines are formed of different materials.

19. The display device according to claim 18,
wherein the plurality of crack detection wiring lines include a first crack detection wiring line and a second crack detection wiring line,
the first crack detection wiring line is provided closer to the display region than the second crack detection wiring line,
the first crack detection wiring line is formed of one or more selected from molybdenum and tungsten, and
the second crack detection wiring line is formed of one or more selected from aluminum, silver, and copper.

20. The display device according to claim 1,
wherein resistance values of two of the plurality of crack detection wiring lines are set in a manner that the resistance value of the crack detection wiring line disposed closer to the display region is 1.68 times greater than the resistance value of the crack detection wiring line disposed farther from the display region.

21. The display device according to claim 20,
wherein a length of the crack detection wiring line disposed closer to the display region is 1.68 times greater than a length of the crack detection wiring line disposed farther from the display region.

22. The display device according to claim 1, further comprising:
a sealing layer covering the display region and a portion of the frame region continuing on from the display region,
wherein at least a portion of a portion surrounding the display region of some crack detection wiring lines including a crack detection wiring line disposed farthest from the display region from among the plurality of crack detection wiring lines is provided on an outer side of an end portion of the sealing layer.

23. The display device according to claim 1, further comprising:
a sealing layer covering the display region and a portion of the frame region continuing on from the display region,
wherein a portion of the plurality of crack detection wiring lines surrounding the display region is covered by the sealing layer.

24-32. (canceled)
